(19) United States
(12) Patent Application Publication
(10) Pub. No.: US 2010/0151392 A1
(43) Pub. Date: Jun. 17, 2010

(54) ANTIREFLECTIVE COATING COMPOSITIONS

(76) Inventors: M. Dalil Rahman, Flemington, NJ (US); Yi Yi, Somerville, NJ (US); Douglas McKenzie, Easton, PA (US); Clement Anyadiegwu, Parlin, NJ (US); Ping-Hung Lu, Bridgewater, NJ (US)

Correspondence Address: AZ ELECTRONIC MATERIALS USA CORP.;ATTENTION: INDUSTRIAL PROPERTY DEPT., 70 MEISTER AVENUE, SOMERVILLE, NJ, 08876, US

(21) Appl. No.: 12/332,501

(22) Filed: Dec. 11, 2008

(51) Int. Cl. G03F 7/20; C08L 83/06

(52) U.S. Cl. 430/313; 525/474; 430/311

(57) ABSTRACT

The present invention relates to an organic spin coatable antireflective coating composition comprising a polymer, a linking component, a crosslinker, and an acid generator. The invention further relates to a process for imaging the present composition.

### FIELD OF INVENTION

The present invention relates to an absorbing antireflective coating composition comprising a polymer with fused aromatic rings in the backbone of the polymer and a linking component, and a process for forming an image using the antireflective coating composition. The process is especially useful for imaging photoresists using radiation in the deep and extreme ultraviolet (UV) region.

### DESCRIPTION OF INVENTION

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon based wafers used for making integrated circuits. The coated substrate is then baked to evaporate any solvent in the photoresist composition and to fix the coating onto the substrate. The baked coated surface of the substrate is next subjected to an image-wise exposure to radiation.

This radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the photoresist.

The trend towards the miniaturization of semiconductor devices has led to the use of new photoresists that are sensitive to lower and lower wavelengths of radiation and has also led to the use of sophisticated multilevel systems to overcome difficulties associated with such miniaturization.

Absorbing antireflective coatings and underlayers in photolithography are used to diminish problems that result from back reflection of light from highly reflective substrates. Two major disadvantages of back reflectivity are thin film interference effects and reflective notching. Thin film interference, or standing waves, result in changes in critical line width dimensions caused by variations in the total light intensity in the photoresist film as the thickness of the photoresist changes or interference of reflected and incident exposure radiation can cause standing wave effects that distort the uniformity of the radiation through the thickness. Reflective notching becomes severe as the photoresist is patterned over reflective substrates containing topographical features, which scatter light through the photoresist film, leading to line width variations, and in the extreme case, forming regions with complete photoresist loss. An antireflective coating coated beneath a photoresist and above a reflective substrate provides significant improvement in lithographic performance of the photoresist. Typically, the bottom antireflective coating is applied on the substrate and then a layer of photoresist is applied on top of the antireflective coating. The antireflective coating is cured to prevent intermixing between the antireflective coating and the photoresist. The photoresist is exposed imagewise and developed. The antireflective coating in the exposed area is then typically dry etched using various etching gases, and the photoresist pattern is thus transferred to the substrate. Multiple antireflective layers and underlayers are being used in new lithographic techniques. In cases where the photoresist does not provide sufficient dry etch resistance, underlayers or antireflective coatings for the photoresist that act as a hard mask and are highly etch resistant during substrate etching are preferred, and one approach has been to incorporate silicon into a layer beneath the organic photoresist layer. Additionally, another high carbon content antireflective or mask layer is added beneath the silicon antireflective layer, which is used to improve the lithographic performance of the imaging process. The silicon layer may be spin coatable or deposited by chemical vapor deposition. Silicon is highly dry etch resistant in processes where O₂ etching is used, and by providing a organic mask layer with high carbon content beneath the silicon antireflective layer, a very large aspect ratio can be obtained. Thus, the organic high carbon mask layer can be much thicker than the photoresist or silicon layer above it. The organic mask layer can be used as a thicker film and can provide better substrate etch masking that the original photoresist.

The present invention relates to a novel organic spin coatable antireflective coating composition or organic mask underlayer which has high carbon content and high dry etch resistance, and can be used between a photoresist layer and the substrate as a single layer of one of multiple layers. Typically, the novel composition can be used to form a layer beneath an essentially etch resistant antireflective coating layer, such as a silicon antireflective coating. The high carbon content in the novel antireflective coating, also known as a carbon hard mask underlayer, allows for a high resolution image transfer with high aspect ratio. The novel composition is useful for imaging photoresists, and also for etching the substrate. The novel composition enables a good image transfer from the photoresist to the substrate, and also reduces reflections and enhances pattern transfer. Additionally, substantially no intermixing is present between the antireflective coating and the film coated above it. The antireflective coating also has good solution stability and forms films with good coating quality, the latter being particularly advantageous for lithography.

### SUMMARY OF THE INVENTION

The present invention relates to a novel organic spin coatable antireflective coating composition comprising
(a) a polymer selected from
(I) a polymer with (i) at least one unit with three or more fused aromatic rings of structure (1) in the backbone of the polymer, (ii) at least one aromatic ring unit of structure (2) where the aromatic ring has a pendant alkylene(fused aromatic) group and a pendant hydroxy group in the backbone of the polymer, and, (iii) at least one unit with an aliphatic moiety B of structure (3) in the backbone of the polymer

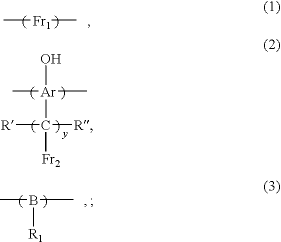

(II) a polymer where the polymer comprises (i) at least one unit with fused aromatic rings of structure (1) in the backbone of the polymer, (ii) at least one unit with structure (2a) in the backbone of the polymer, and, (iii) at least one unit with a cyclic aliphatic moiety D of structure (3a) in the backbone of the polymer

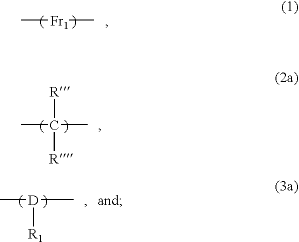

(III) a polymer comprising at least one unit with 3 or more fused aromatic rings Fr₁ in the backbone of the polymer and at least one unit with an aliphatic moiety in the backbone of the polymer,
where Fr₁ is a substituted or unsubstituted fused aromatic ring moiety with 3 or more fused aromatic rings, Fr₂ is a fused aromatic ring moiety with 2 or more fused aromatic rings, Ar is a substituted or unsubstituted aromatic ring moiety, R′ and R″ are independently selected from hydrogen and C₁-C₄ alkyl, R′″ and R″″ are independently selected from hydrogen, C₁-C₄ alkyl, Z, C₁-C₄alkyleneZ where Z is substituted or unsubstituted aromatic moiety, y=1-4, B is a substituted or unsubstituted aliphatic moiety, D is a substituted or unsubstituted cycloaliphatic moiety, and R₁ is selected from hydrogen or aromatic moiety; (b) a linking component having at least two halogen atoms, at least two alkoxy groups or at least one halogen atom and at least one alkoxy group; (c) a crosslinker; and (d) an acid generator. The invention further relates to a process for imaging the present composition.

### BRIEF DESCRIPTION OF DRAWINGS

FIG. 1 shows examples of aliphatic comonomeric units.

FIG. 2 illustrates the process of imaging.

### DETAILED DESCRIPTION OF THE INVENTION

The present invention relates to a novel organic spin coatable antireflective coating composition comprising
(a) a polymer selected from
(I) a polymer with (i) at least one unit with three or more fused aromatic rings of structure (1) in the backbone of the polymer, (ii) at least one aromatic ring unit of structure (2) where the aromatic ring has a pendant alkylene(fused aromatic) group and a pendant hydroxy group in the backbone of the polymer, and, (iii) at least one unit with an aliphatic moiety B of structure (3) in the backbone of the polymer

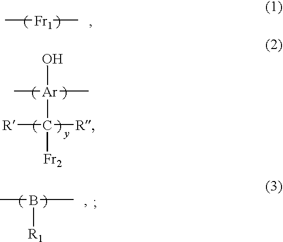

(II) a polymer where the polymer comprises (i) at least one unit with fused aromatic rings of structure (1) in the backbone of the polymer, (ii) at least one unit with structure (2a) in the backbone of the polymer, and, (iii) at least one unit with a cyclic aliphatic moiety D of structure (3a) in the backbone of the polymer

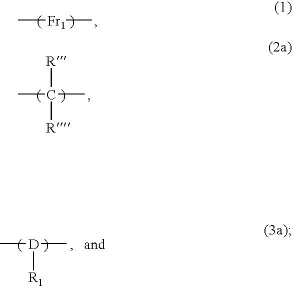

(III) a polymer comprising at least one unit with 3 or more fused aromatic rings Fr₁ in the backbone of the polymer and at least one unit with an aliphatic moiety in the backbone of the polymer,
where Fr₁ is a substituted or unsubstituted fused aromatic ring moiety with 3 or more fused aromatic rings, Fr₂ is a fused aromatic ring moiety with 2 or more fused aromatic rings, Ar is a substituted or unsubstituted aromatic ring moiety, R′ and R″ are independently selected from hydrogen and C₁-C₄ alkyl, R′″ and R″″ are independently selected from hydrogen, C₁-C₄ alkyl, Z, C₁-C₄alkyleneZ where Z is substituted or unsubstituted aromatic moiety, y=1-4, B is a substituted or unsubstituted aliphatic moiety, D is a substituted or unsubstituted cycloaliphatic moiety, and R₁ is selected from hydrogen or aromatic moiety; (b) a linking component having at least two halogen atoms, at least two alkoxy groups or at least one halogen atom and at least one alkoxy group; (c) a crosslinker; and (d) an acid generator. The invention also relates to a process for imaging a photoresist layer coated above the novel antireflective coating layer.

The novel antireflective coating of the present invention comprises a polymer with high carbon content which is capable of crosslinking, such that the coating becomes insoluble in the solvent of the material coated above it. The novel coating composition is capable of self-crosslinking or may additionally comprise a crosslinking compound capable of crosslinking with the polymer. The composition may additionally comprise other additives, such as organic acids, thermal acid generators, photoacid generators, surfactants, other high carbon content polymers etc. The solid components of the novel composition are dissolved in an organic coating solvent composition, comprising one or more organic solvents.

The polymer is selected from
(I) a polymer with (i) at least one unit with three or more fused aromatic rings of structure (1) in the backbone of the polymer, (ii) at least one aromatic ring unit of structure (2) where the aromatic ring has a pendant alkylene(fused aromatic) group and a pendant hydroxy group in the backbone of the polymer, and, (iii) at least one unit with an aliphatic moiety B of structure (3) in the backbone of the polymer

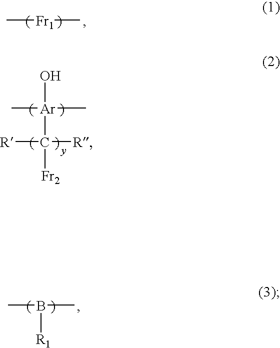

(II) a polymer where the polymer comprises (i) at least one unit with fused aromatic rings of structure (1) in the backbone of the polymer, (ii) at least one unit with structure (2a) in the backbone of the polymer, and, (iii) at least one unit with a cyclic aliphatic moiety D of structure (3a) in the backbone of the polymer

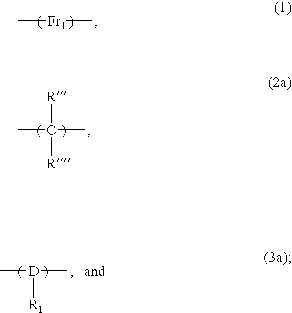

(III) a polymer comprising at least one unit with 3 or more fused aromatic rings Fr₁ in the backbone of the polymer and at least one unit with an aliphatic moiety in the backbone of the polymer,
where Fr₁ is a substituted or unsubstituted fused aromatic ring moiety with 3 or more fused aromatic rings, Fr₂ is a fused aromatic ring moiety with 2 or more fused aromatic rings, Ar is a substituted or unsubstituted aromatic ring moiety, R′ and R″ are independently selected from hydrogen and C₁-C₄ alkyl, R′″ and R″″ are independently selected from hydrogen, C₁-C₄ alkyl, Z, C₁-C₄alkyleneZ where Z is substituted or unsubstituted aromatic moiety, y=1-4, B is a substituted or unsubstituted aliphatic moiety, D is a substituted or unsubstituted cycloaliphatic moiety, and R₁ is selected from hydrogen or aromatic moiety;

Polymer (I) of the present novel composition comprises (i) at least one unit with fused aromatic rings in the backbone of the polymer of structure (1), (ii) at least one aromatic unit ring in the backbone of the polymer of structure (2) where the aromatic ring has a pendant alkylene(fused aromatic) group and a pendant hydroxy group, and, (iii) at least one unit with an aliphatic moiety in the backbone of the polymer of structure (3).

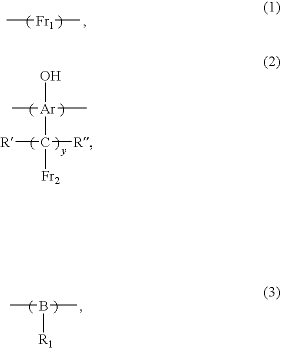

where Fr₁ is a substituted or unsubstituted fused aromatic ring moiety with 3 or more fused aromatic rings, Fr₂ is a fused aromatic ring moiety with 2 or more fused aromatic rings, Ar is a substituted or unsubstituted aromatic ring moiety, R′ and R″ are independently selected from hydrogen and C₁-C₄ alkyl, y=1-4, R₁ is selected from hydrogen or aromatic moiety and B is a substituted or unsubstituted aliphatic moiety. The unit may further comprise a unit with an aromatic moiety in the backbone of the unit and where the aromatic moiety has a pendant hydroxy group. Also in the polymer, Ar may be substituted with a C₁-C₄ alkyl group.

Polymer (II) of the present novel composition comprises (i) at least one unit with fused aromatic rings in the backbone of the polymer of structure (1), (ii) at least one unit with structure (2a) in the backbone of the polymer, and, (iii) at least one unit with a cyclic aliphatic moiety D in the backbone of the polymer of structure (3a)

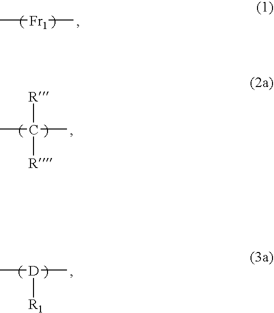

where Fr₁ and R₁ are described above, R′″ and R″″ are independently selected from hydrogen, C₁-C₄ alkyl, Z, C₁-C₄alkyleneZ where Z is substituted or unsubstituted aromatic moiety, and D is a substituted or unsubstituted cycloaliphatic moiety.

Polymer (III) of the present novel composition comprises at least one unit with 3 or more fused aromatic rings Fr₁ in the backbone of the polymer and at least one unit with an aliphatic moiety in the backbone of the polymer. Other comonomeric units may also be present, such as substituted or unsubstituted phenyl, or substituted or unsubstituted naphthyl. In some embodiments, the polymer may be free of any phenyl or single ring aromatic moiety.

The fused aromatic rings in the backbone of the polymers (I), (II), and (III) of the present novel composition provide the absorption for the coating, and are the absorbing chromophore. The fused aromatic rings of the polymer can comprise 6 membered aromatic rings which have a common bond to form a fused ring structure, such as units exemplified by structures 4-9 and their isomers,

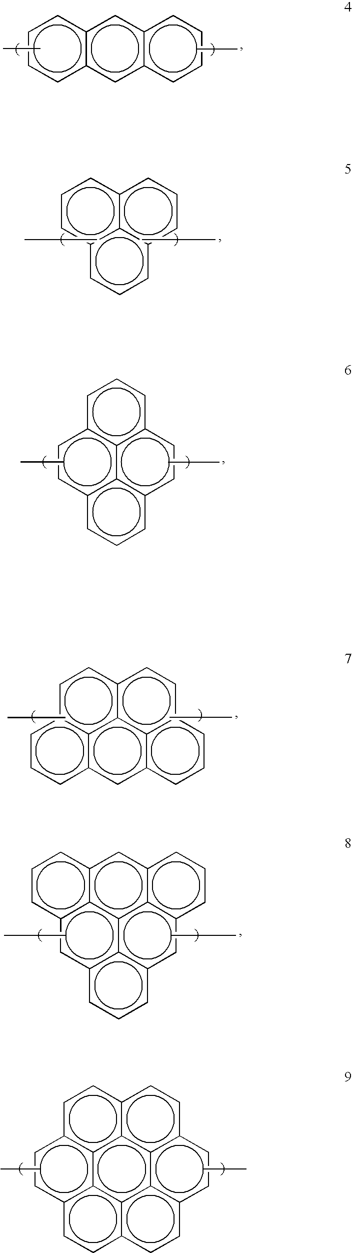

The fused rings may be exemplified by anthracene, phenanthrene, pyrene, fluoranthene, and coronene triphenylene.

The fused rings may form the backbone of the polymer at any site in the aromatic structure and the attachment sites may vary within the polymer. The fused ring structure can have more than 2 points of attachment forming a branched oligomer or branched polymer. In one embodiment of the present invention the number of fused aromatic rings may vary from 3-8, and in other embodiment of the polymer it comprises 4 or more fused aromatic rings, and more specifically the polymer may comprise pyrene as shown in structure 6. The fused aromatic rings may comprise one or more hetero-aromatic rings, where the heteroatom may be nitrogen or sulfur, as illustrated by structure 10.

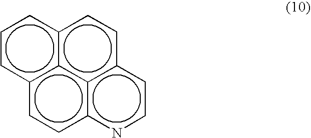

In order to isolate the chromophore, the fused aromatic unit is connected to an aliphatic carbon moiety. The fused aromatic rings of the polymer may be unsubstituted or substituted with one or more organo substituents, such as alkyl, alkylaryl, ethers, haloalkyls, carboxylic acid, esters of carboxylic acid, alkylcarbonates, alkylaldehydes, and ketones. Further examples of substituents are —CH₂—OH, —CH₂Cl, —CH₂Br, —CH₂Oalkyl, —CH₂—O—C═O(alkyl), —CH₂—O—C═O(O-alkyl), —CH(alkyl)-OH, —CH(alkyl)-Cl, —CH(alkyl)-Br, —CH(alkyl)-O-alkyl, —CH(alkyl)-O—C═O-alkyl, —CH(alkyl)-O—C═O(O-alkyl), —HC═O, -alkyl-CO₂H, alkyl-C═O(O-alkyl), -alkyl-OH, -alkyl-halo, -alkyl-O—C═O(alkyl), -alkyl-O—C═O(O-alkyl), alkyl-HC═O. In one embodiment of the polymer, the fused aromatic group is free of any pendant moiety containing nitrogen. In one embodiment of unit (i) the fused aromatic group is free of any pendant moiety. The substituents on the fused aromatic rings may aid in the solubility of the polymer in the coating solvent. Some of the substituents on the fused aromatic structure may also be thermolysed during curing, such that they may not remain in the cured coating and may still give a high carbon content film useful during the etching process. The substituted fused aromatic groups are more generally illustrated by structures 4′ to 9′, where Rₐ is an organo substituent, such as hydrogen, hydroxy, hydroxy alkylaryl, alkyl, alkylaryl, carboxylic acid, ester of carboxylic acid, etc., and n is the number of substituents on the rings. The substituents, n, may range from 1-12. Typically n can range from 1-5, where Rₐ, exclusive of hydrogen, is a substituent independently selected from groups such as alkyl, hydroxy, hydroxyalkyl, hydroxyalkylaryl, alkylaryl, ethers, haloalkyls, alkoxy, carboxylic acid, esters of carboxylic acid, alkylcarbonates, alkylaldehydes, and ketones. Further examples of substituents are —CH₂—OH, —CH₂Cl, —CH₂Br, —CH₂Oalkyl, —CH₂—O—C═O(alkyl), —CH₂—O—C═O(O-alkyl), —CH(alkyl)-OH, —CH(alkyl)-Cl, —CH(alkyl)-Br, —CH(alkyl)-O-alkyl, —CH(alkyl)-O—C═O-alkyl, —CH(alkyl)-O—C═O(O-alkyl), —HC═O, -alkyl-CO₂H, alkyl-C═O(O-alkyl), -alkyl-OH, -alkyl-halo, -alkyl-O—C═O(alkyl), -alkyl-O—C═O(O-alkyl), alkyl-HC═O.

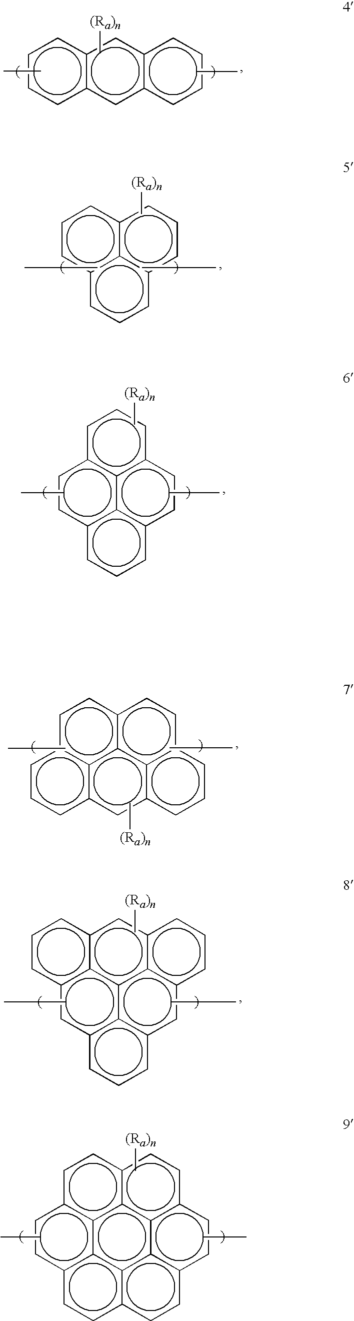

The polymer may comprise more than one type of the fused aromatic structures described herein.

For polymer (I), the aromatic unit (ii) of structure (2) with an alkylene(fused aromatic) group pendant from an aromatic hydroxy group, of the present composition, is shown below,

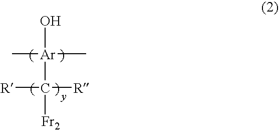

where Fr₂ is a fused aromatic ring moiety with 2 or more fused aromatic rings, Ar is a substituted or unsubstituted aromatic ring moiety or aryl, R′ and R″ are independently selected from hydrogen and C₁-C₄ alkyl and y=1-4. The number of aromatic rings in the fused aromatic group, Fr₂, can range from 2-7. Ar may be unsubstituted or be substituted with a C₁-C₄ alkyl group such as methyl, ethyl and isopropyl. Ar may be selected from phenyl, naphthyl, phenanthryl, and anthracyl. R′ and R″ may be selected from hydrogen, linear C₁-C₄ alkyl and branched C₁-C₄ alkyl, such as methyl, ethyl, isopropyl etc. Examples of the pendant alkylene group, R′(C)_{y}R″, are methylene, ethylene, isopropylene, butylenes, etc. Fr₂ may be selected from fused aromatics with 2 or more aromatic rings, such as naphthyl, anthracyl, pyrenyl, etc.

The unit (ii) in polymer (I) may be further illustrated by the structure (11) and (12) below,

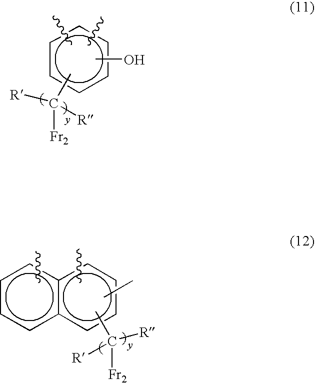

where the phenyl or naphthyl group forms part of the backbone of the polymer, Fr₂ is a fused aromatic ring with 2 or more fused aromatic rings, R′ and R″ are independently selected from hydrogen and C₁-C₄ alkyl and y is 1-4. The alkylene group R′(C)_{y}R″ connecting the two aromatic moieties can be linear or branched, and may be methylene or ethylene or isopropylene or butylene. The fused aromatic ring can be naphthyl, anthracyl, pyrenyl, etc. The number of aromatic rings in the fused aromatic group, Fr₂, can range from 2-7. The aromatic rings may be unsubstituted or substituted with C₁-C₄ alkyl groups. The unit (ii) allows the aromatic content of the polymer/composition to be increased to formulate a composition capable of forming a film with high dry etch resistance and also a high carbon content. Examples of the unit are given below as structures 13-18, where y=1-4

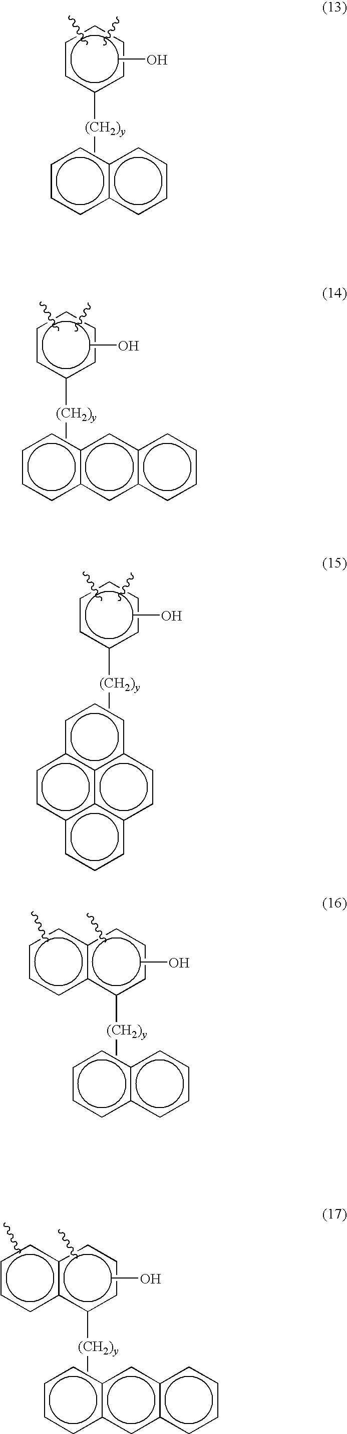

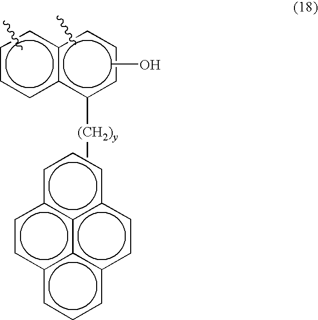

For polymer (I), an additional aromatic unit may be present in the backbone of the polymer where the aromatic unit has a pendant hydroxy group and may be exemplified by phenyl, biphenyl and naphthyl with a pendant hydroxy group. Other alkyl substituents may be also present on the aromatic unit, such as C₁-C₄ alkyl groups. The alkylene(fused aroaromatic) group of structure (2) is not present in this additional unit. The hydroxy substituent on the aromatics is a polar group that increases the solubility of the polymer in a polar solvent, such as ethyl lactate, PGMEA and PGME. Examples of such monomeric units may be derived from monomers such as phenol, hydroxycresol, dihydroxyphenol, naphthol, and dihydroxynaphthylene. The incorporation of phenol and/or naphthol moieties in the polymer backbone is preferred for films with high carbon content. The amount of the hydroxyaromatic unit present in polymer (I) may range from about 0 mole % to about 30 mole % in the polymer, or from about 5 mole % to about 30 mole %, or from about 25 mole % to about 30 mole % in the polymer. Compositions comprising polymer (I) of the present invention which comprise phenolic and/or naphthol groups are useful when the coating solvent of the composition is PGMEA or a mixture of PGMEA and PGME. Compositions comprising polymers of the present invention which comprise phenolic and/or naphthol groups are also useful when the excess composition is to be removed with an edgebead remover, especially where the edgebead remover comprises PGMEA or a mixture of PGMEA and PGME. Other edgebead removers comprising ethyl lactate may also be used. This present unit in polymer (I) may be derived from monomers such as phenol, naphthol and mixtures thereof.

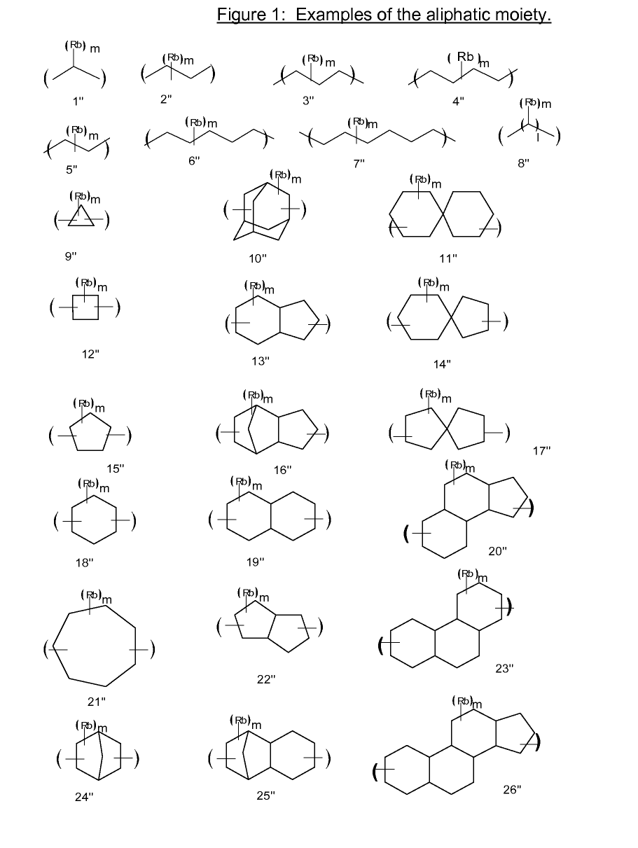

Unit (iii) of polymer (I) with an essentially aliphatic moiety in the backbone is any that has a nonaromatic structure that forms the backbone of the polymer, such as an alkylene which is primarily a carbon/hydrogen nonaromatic moiety. Pendant aryl or substituted aryl groups may be pendant from the moiety which is aliphatic and forms the backbone of the polymer. The polymer (I) can comprise at least one unit which forms only an aliphatic backbone in polymer (I), and the polymer (I) may be described by units, -(A)- and -(BR₁)-, where A represents the different units with aromatic moieties described previously, and where B has only an aliphatic backbone. B may further have pendant substituted or unsubstituted aryl or aralkyl groups or be connected to form a branched polymer or have other substituents. The alkylene aliphatic moiety, B, in polymer (I) may be selected from a moiety which is unsubstituted or substituted linear, unsubstituted or substituted branched, unsubstituted or substituted cyclic or a mixture thereof. Multiple types of the alkylene units may be in the polymer. In one embodiment the alkylene unit (iii) in polymer (I) may be a nonaromatic unit. The substituted or unsubstituted alkylene backbone moiety, B, may comprise some pendant groups, such as hydroxy, hydroxyalkyl, alkyl, alkene, alkenealkyl, alkylalkyne, alkyne, alkoxy, ether, carbonate, halo (e.g. Cl, Br). The aromatic group, R₁ may be aryl, alkylaryl, aralkyl, aralkyl ester, etc. Pendant groups can impart useful properties to the polymer. Some of the pendant groups may be thermally eliminated during curing to give a polymer with high carbon content, for example through crosslinking or elimination to form an unsaturated bond. Alkylene groups such as hydroxyadamantylene, hydroxycyclohexylene, olefinic cycloaliphatic moiety, may be present in the backbone of the polymer. These groups can also provide crosslinking sites for crosslinking the polymer during the curing step. Pendant groups on the alkylene moiety, such as those described previously, can enhance solubility of the polymer in organic solvents, such as coating solvents of the composition or solvents useful for edge bead removal. More specific groups of the aliphatic comonomeric unit are exemplified by adamantylene, dicyclopentylene, and hydroxy adamantylene. The structures of some of the comonomeric unit are given in structures 1″ to 26″ in FIG. 1, where R_{b} is independently selected from hydrogen, hydroxy, hydroxyalkyl, alkyl, alkylaryl, ethers, halo, haloalkyls, carboxylic acid, ester of carboxylic acid, alkylcarbonates, alkylaldehydes, ketones, and other known substituents, and m is the number of substituents. The number, m, may range from 1-40, depending on the size of the unit. Different or the same alkylene group may be connected together to form a block unit and this block unit may be then connected to the unit comprising the fused aromatic rings. In some cases a block copolymer may be formed, in some case a random copolymer may be formed, and in other cases alternating copolymers may be formed. The copolymer may comprise at least 2 different aliphatic comonomeric units, such as a cyclic unit and linear or branched unit. The copolymer may comprise at least 2 different fused aromatic moieties. In one embodiment the polymer may comprise at least 2 different aliphatic comonomeric units and at least 2 different fused aromatic moieties. In another embodiment of the invention the polymer comprises at least one fused aromatic unit and aliphatic unit(s) free of aromatics. In one embodiment of the unit in polymer (I) with the aliphatic group, the cycloalkylene group is selected from a biscycloalkylene group, a triscycloalkylene group, a tetracycloalkylene group in which the linkage to the polymer backbone is through the cyclic structure and these cyclic structures form either a monocyclic, a dicyclic or tricyclic structure. In another embodiment of the polymer, the polymer comprises a unit with the fused aromatic rings and a unit with an aliphatic moiety in the backbone, where the aliphatic moiety is a mixture of unsubstituted alkylene and a substituted alkylene where the substituent may be hydroxy, carboxylic acid, carboxylic ester, alkylether, alkoxy alkyl, alkylaryl, ethers, haloalkyls, alkylcarbonates, alkylaldehydes, ketones and mixtures thereof. Polymer (I) is more fully described in copending patent application Ser. No. 12/270,189, filed Nov. 13, 2008, the contents of which are hereby incorporated herein by reference.

For polymer (II) of the present inventive composition unit (i), Fr₁ is as described above for the fused aromatic rings; see for example the discussion regarding structures 4 to 9 and 4′ to 9′ and structure 10 as well as the substituents described above.

For polymer (II), unit (ii) with the substituted or unsubstituted alkylene group is shown by structure (2a), where R′″ and R″″ are independently selected from hydrogen, C₁-C₄ alkyl, Z, C₁-C₄alkyleneZ and where Z is substituted or unsubstituted aromatic moiety,

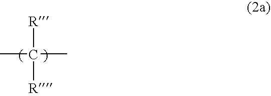

The aromatic moiety may be exemplified by substituted or unsubstituted phenyl, substituted or unsubstituted naphthyl, substituted or unsubstituted anthracyl, substituted or unsubstituted pyrenyl etc. The substituted aromatic may be an aromatic substituted with hydroxy, C₁-C₄ alkyl, alkenyl, aryl or mixtures thereof. Examples of Z are below where R is selected from C₁ to C₁₀ alkyl, C₁ to C₁₀ alkenyl, aryl and mixtures.

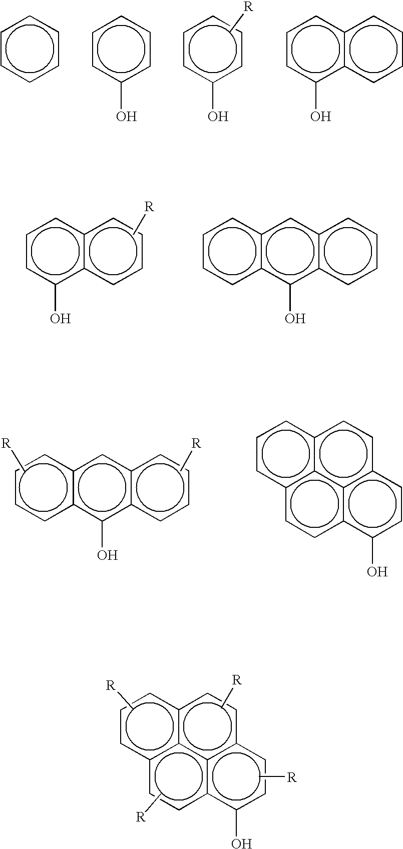

Z may be substituted or unsubstituted phenyl, hydroxy phenyl such as phenol, fused ring phenols such as naphthol, hydroxyl anthracene, and hydroxyl pyrene.

In one embodiment of unit (ii) in polymer (II), the aromatic moiety is phenyl or hydroxyphenyl. The monomeric unit from which unit (ii) of polymer (II) may be derived can be different forms of formaldehyde, acetaldehyde, benzaldehyde, hyroxybenzaldehyde, substituted benzaldehyde, substituted hydroxybenzaldehyde, etc.

Unit (iii) of polymer (II) with an essentially cycloaliphatic moiety in the backbone of the polymer is any that has a nonaromatic structure that forms the backbone of the polymer, such as an alkylene which is primarily a carbon/hydrogen nonaromatic moiety. Aryl or substituted aryl groups may be pendant from the moiety which is cycloaliphatic and forms the backbone of polymer (II). D in unit (iii) of polymer (II) has only a cycloaliphatic backbone. D may further have pendant substituted or unsubstituted aryl or aralkyl groups or be connected to form a branched polymer or have other substituents. Multiple types of the alkylene units may be in the polymer. D may be monocyclic or muticyclic, such as 3-8 membered monocyclic rings, adamantylene, norbornylene, dicyclopentylene, etc. and those illustrated in structures 9″ to 26″ in FIG. 1. In one embodiment the alkylene unit (iii) in polymer (II) may be a nonaromatic unit. The substituted or unsubstituted cycloalkylene backbone moiety, D, may comprise some pendant groups, such as hydroxy, hydroxyalkyl, alkyl, alkene, alkenealkyl, alkylalkyne, alkyne, alkoxy, ether, carbonate, halo (e.g. Cl, Br). When R₁ is an aromatic group, it may be unsubstituted or substituted aryl, alkylaryl, aralkyl, aralkyl ester, etc. Pendant groups can impart useful properties to the polymer. Some of the pendant groups may be thermally eliminated during curing to give a polymer with high carbon content, for example through crosslinking or elimination to form an unsaturated bond. Cycloalkylene groups such as hydroxyadamantylene, hydroxycyclohexylene, olefinic cycloaliphatic moiety, may be present in the backbone of the polymer. These groups can also provide crosslinking sites for crosslinking the polymer during the curing step. Pendant groups on the alkylene moiety, such as those described previously, can enhance solubility of the polymer in organic solvents, such as coating solvents of the composition or solvents useful for edge bead removal. More specific groups of the aliphatic comonomeric unit are exemplified by adamantylene, dicyclopentylene, and hydroxy adamantylene. The structures of some of the comonomeric unit are given in structures 9″ to 26″ of FIG. 1, where R_{b} is an organo substituent exemplified by hydroxy, hydroxyalkyl, alkyl, alkylaryl, ethers, halo, haloalkyls, carboxylic acid, ester of carboxylic acid, alkylcarbonates, alkylaldehydes, ketones, and other known substituents, and m is the number of substituents. The number, m, may range from 1-40, depending on the size of the unit. Different or the same alkylene group may be connected together to form a block unit and this block unit may be then connected to the unit comprising the fused aromatic rings. In some cases a block copolymer may be formed, in some cases a random copolymer may be formed, and in other cases alternating copolymers may be formed. The copolymer may comprise at least 2 different cycloaliphatic comonomeric units. The copolymer may comprise at least 2 different fused aromatic moieties. In one embodiment polymer (II) may comprise at least 2 different cycloaliphatic comonomeric units and at least 2 different fused aromatic moieties, together with the unit of structure (2a) of polymer (II). In one embodiment of the unit with the cycloaliphatic group, the cycloalkylene group is selected from a biscycloalkylene group, a triscycloalkylene group, a tetracycloalkylene group in which the linkage to the polymer backbone is through the cyclic structure and these cyclic structures form either a monocyclic, a dicyclic or tricyclic structure. In another embodiment of the polymer, the polymer comprises a unit with the fused aromatic rings, unit with the methylene structure, and a unit with an cycloaliphatic moiety in the backbone, where the aliphatic moiety is a mixture of unsubstituted cycloalkylene and a substituted cycloalkylene where the substituent may be hydroxy, carboxylic acid, carboxylic ester, alkylether, alkoxy alkyl, alkylaryl, ethers, haloalkyls, alkylcarbonates, alkylaldehydes, ketones and mixtures thereof.

In one embodiment of polymer (II) of the present invention, polymer (II) comprises at least one unit with 3 or more substituted or unsubstituted fused aromatic rings in the backbone of polymer (II) of structure (1), at least one unit with an aliphatic moiety of structure (2a) in the backbone of polymer (II), at least one unit with a cycloaliphatic moiety of structure (3a) in the backbone of polymer (II), and at least one aromatic unit in the backbone of polymer (II) where the aromatic unit has at least one pendant hydroxy group and may be exemplified by phenyl, biphenyl and naphthyl with a pendant hydroxy group. Other alkyl substituents may be also present on the aromatic unit, such as C₁-C₄ alkyl groups, C₁-C₁₀alkylene(fused aromatic) group. The fused aromatic ring with 3 or more aromatic units and the aliphatic moiety are as described herein. Polymer (II) may be free of any pendant moiety containing nitrogen, in one embodiment. The hydroxy substituent on the aromatics is a polar group that increases the solubility of polymer (II) in a polar solvent, such as ethyl lactate, PGMEA and PGME. Examples of such monomeric units may be derived from monomers such as phenol, hydroxycresol, dihydroxyphenol, naphthol, and dihydroxynaphthylene. The incorporation of phenol and/or naphthol moieties in the polymer (II) backbone is preferred for films with high carbon content. The amount of the hydroxyaromatic unit present in polymer (II) may range from about 0 mole % to about 30 mole % in polymer (II), or from about 5 mole % to about 30 mole %, or from about 25 mole % to about 30 mole % in polymer (II). Compositions comprising polymer (II) of the present invention which comprise phenolic and/or naphthol groups are useful when the coating solvent of the composition is PGMEA or a mixture of PGMEA and PGME. Compositions comprising polymer (II)of the present invention which comprise phenolic and/or naphthol groups are also useful when the excess composition is to be removed with an edgebead remover, especially where the edgebead remover comprises PGMEA or a mixture of PGMEA and PGME. Other edgebead removers comprising ethyl lactate may also be used. The present unit of polymer (II) may be derived from monomers such as phenol, naphthol and mixtures thereof. Polymer (II) is more fully described in copending patent application Ser. No. 12/270,256, filed Nov. 13, 2008, the contents of which are hereby incorporated herein by reference.

Polymer (III) comprises at least one unit with three or more fused aromatic rings in the backbone of the polymer and at least one unit with an aliphatic moiety in the backbone of the polymer. Other comonomeric units may also be present, such as substituted or unsubstituted phenyl, or substituted or unsubstituted naphthyl. In one embodiment the polymer may be free of any phenyl or single ring aromatic moiety. The fused aromatic rings provide the absorption for the coating, and are the absorbing chromophore. The fused aromatic rings of the polymer are described above; see for example the discussion regarding structures 4 to 9 and 4′ to 9′ and structure 10 as well as the substituents described above.

In addition to the fused aromatic unit, polymer (III) of the novel antireflective coating further comprises at least one unit with an essentially aliphatic moiety in the backbone of the polymer, and the moiety is any that has a nonaromatic structure that forms the backbone of the polymer, such as an alkylene which is primarily a carbon/hydrogen nonaromatic moiety. The polymer can comprise at least one unit which forms only an aliphatic backbone in the polymer, and the polymer may be described by comprising units, -(A)- and -(B)-, where A is any fused aromatic unit described previously, which may be linear or branched, and where B has only an aliphatic backbone. B may further have pendant substituted or unsubstituted aryl or aralkyl groups or be connected to form a branched polymer. The alkylene, aliphatic moiety in the polymer may be selected from a moiety which is unsubstituted or substituted linear, unsubstituted or substituted branched, unsubstituted or substituted cyclic or a mixture thereof. Multiple types of the alkylene units may be in the polymer. The alkylene backbone unit may have some pendant groups present, such as hydroxy, hydroxyalkyl, alkyl, alkene, alkenealkyl, alkylalkyne, alkyne, alkoxy, aryl, alkylaryl, aralkyl ester, ether, carbonate, halo (e.g. Cl, Br). Pendant groups can impart useful properties to the polymer. Some of the pendant groups may be thermally eliminated during curing to give a polymer with high carbon content, for example through crosslinking or elimination to form an unsaturated bond. Alkylene groups such as hydroxyadamantylene, hydroxycyclohexylene, olefinic cycloaliphatic moiety, may be present in the backbone of the polymer. These groups can also provide crosslinking sites for crosslinking the polymer during the curing step. Pendant groups on the alkylene moiety, such as those described previously, can enhance solubility of the polymer in organic solvents, such as coating solvents of the composition or solvents useful for edge bead removal. More specific groups of the aliphatic comonomeric unit are exemplified by adamantylene, dicyclopentylene, and hydroxy adamantylene. The structures of some of the alkylene moieties are given in structures 1″ to 26″ of FIG. 1, where R_{b} is independently selected from hydrogen, hydroxy, hydroxyalkyl, alkyl, alkylaryl, ethers, halo, haloalkyls, carboxylic acid, ester of carboxylic acid, alkylcarbonates, alkylaldehydes, ketones, and other known substituents, and m is the number of substituents. The number, m, may range from 1-40, depending on the size of the unit. Different or the same alkylene group may be connected together to form a block unit and this block unit may be then connected to the unit comprising the fused aromatic rings. In some cases a block copolymer may be formed, in some case a random copolymer may be formed, and in other cases alternating copolymers may be formed. The copolymer may comprise at least 2 different aliphatic comonomeric units. The copolymer may comprise at least 2 different fused aromatic moieties. In one embodiment the polymer may comprise at least 2 different aliphatic comonomeric units and at least 2 different fused aromatic moieties. In another embodiment of the invention the polymer comprises at least one fused aromatic unit and aliphatic unit(s) free of aromatics. In one embodiment of the unit with the aliphatic group, the cycloalkylene group is selected from a biscycloalkylene group, a triscycloalkylene group, a tetracycloalkylene group in which the linkage to the polymer backbone is through the cyclic structure and these cyclic structures form either a monocyclic, a dicyclic or tricyclic structure. In another embodiment of the polymer, the polymer comprises a unit with the fused aromatic rings and a unit with an aliphatic moiety in the backbone, where the aliphatic moiety is a mixture of unsubstituted alkylene and a substituted alkylene where the substituent may be hydroxy, carboxylic acid, carboxylic ester, alkylether, alkoxy alkyl, alkylaryl, ethers, haloalkyls, alkylcarbonates, alkylaldehydes, ketones and mixtures thereof.

Some examples of polymeric units of polymer (III) include

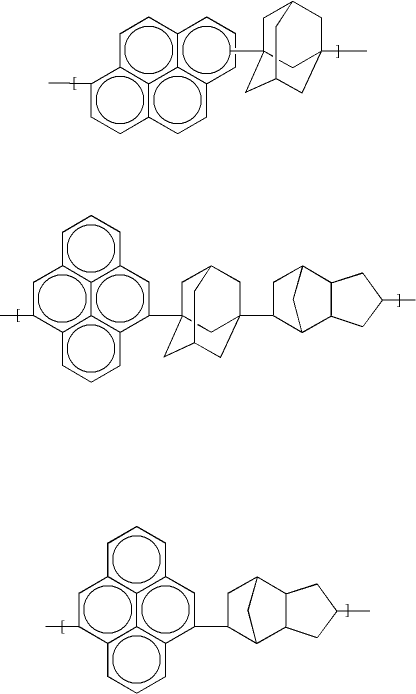

In one embodiment of polymer (III), polymer (III) comprises at least one unit with 3 or more fused aromatic rings in the backbone of polymer (III), at least one unit with an aliphatic moiety in the backbone of polymer (III), and at least one unit comprising a group selected from a substituted phenyl, unsubstituted phenyl, unsubstituted biphenyl, substituted biphenyl, substituted naphthyl and unsubstituted naphthyl. The fused aromatic ring with 3 or more aromatic units and the aliphatic moiety are as described herein. The polymer (III) may be free of any pendant moiety containing nitrogen. The polymer (III)may be free of any pendant moiety containing nitrogen, in one embodiment. The substituents on the phenyl, biphenyl and naphthyl may be at least one polar group that increases the solubility of polymer (III) in a polar solvent, such as ethyl lactate, PGMEA and PGME. Examples of substituents are hydroxy, hydroxyalkyl, halide, etc. The phenyl, biphenyl or naphthyl group may form part of the backbone or be attached to the polymer (III) backbone directly or through a linking group such as a adamantyl group, ethylene group, etc., and where examples of monomeric units may be derived from monomers such as hydroxystyrene, phenol, naphthol, and hydroxynaphthylene. The incorporation of phenol and/or naphthol moieties in the polymer (III) backbone is preferred for films with high carbon content. The amount of the substituted phenyl, unsubstituted phenyl, unsubstituted biphenyl, substituted biphenyl, substituted naphthyl or unsubstituted naphthyl may range from about 5 mole % to about 50 mole % in polymer (III), or from about 20 mole % to about 45 mole % in polymer (III). Compositions comprising polymer (III) which further comprise phenolic and/or naphthol groups are useful when the coating solvent of the composition is PGMEA or a mixture of PGMEA and PGME. Compositions comprising polymer (III) which further comprise phenolic and/or naphthol groups are also useful when the excess composition is to be removed with an edgebead remover, especially where the edgebead remover comprises PGMEA or a mixture of PGMEA and PGME. Other edgebead removers comprising ethyl lactate may also be used. In one embodiment the composition comprises polymer (III) comprising at least one unit with 3 or more fused aromatic rings in the backbone of polymer (III), at least one unit with an aliphatic moiety in the backbone of polymer (III), and at least one unit comprising a group selected from phenol, naphthol and mixtures thereof. Pyrene, as the fused aromatic moiety, may be used. Polymer (III) is more fully described in copending patent applications Ser. No. 11/752,040, filed May 22, 2007, and Ser. No. 11/872,962, filed Oct. 16, 2007, the contents of which are hereby incorporated herein by reference.

As described herein, alkylene, may be linear alkylene, branched alkylene or cycloaliphatic alkylene (cycloalkylene). Alkylene groups are divalent alkyl groups derived from any of the known alkyl groups and may contain up to about 20-30 carbon atoms. The alkylene monomeric unit can comprise a mixture of cycloalkene, linear and/or branched alkylene units, such as —CH₂-cyclohexanyl-CH₂—). When referring to alkylene groups, these may also include an alkylene substituted with (C₁-C₂₀)alkyl groups in the main carbon backbone of the alkylene group. Alkylene groups can also include one or more alkene and or alkyne groups in the alkylene moiety, where alkene refers to a double bond and alkyne refers to a triple bond. The unsaturated bond(s) may be present within the cycloaliphatic structure or in the linear or branched structure, but preferably not in conjugation with the fused aromatic unit. The alkyene moiety may itself be an unsaturated bond comprising a double or triple bond. The alkylene group may contain substituents such as, hydroxy, hydroxyalkyl, carboxylic acid, carboxylic ester, alkylether, alkoxy alkyl, alkylaryl, ethers, haloalkyls, alkylcarbonates, alkylaldehydes, and ketones. Further examples of substituents are —CH₂—OH, —CH₂Cl, —CH₂Br, —CH₂Oalkyl, —CH₂—O—C═O(alkyl), —CH₂—O—C═O(O-alkyl), —CH(alkyl)-OH, —CH(alkyl)-Cl, —CH(alkyl)-Br, —CH(alkyl)-O-alkyl, —CH(alkyl)-O—C═O-alkyl, —CH(alkyl)-O—C═O(O-alkyl), —HC═O, -alkyl-CO₂H, alkyl-C═O(O-alkyl), -alkyl-OH, -alkyl-halo, -alkyl-O—C═O(alkyl), -alkyl-O—C═O(O-alkyl), and alkyl-HC═O. In one embodiment the alkylene backbone may have aryl substituents. Essentially an alkylene moiety is at least a divalent hydrocarbon group, with possible substituents. Accordingly, a divalent acyclic group may be methylene, ethylene, n-or iso-propylene, n-iso, or tert-butylene, linear or branched pentylene, hexylene, heptylene, octylene, decylene, dodecylene, tetradecylene and hexadecylene. 1,1- or 1,2-ethylene, 1,1-, 1,2-, or 1,3 propylene, 2,5-dimethyl-3-hexene, 2,5-dimethyl-hex-3-yne, and so on. Similarly, a divalent cyclic alkylene group may be monocyclic or multicyclic containing many cyclic rings. Monocyclic moieties may be exemplified by 1,2- or 1,3-cyclopentylene, 1,2-, 1,3-, or 1,4-cyclohexylene, and the like. Bicyclo alkylene groups may be exemplified by bicyclo[2.2.1]heptylene, bicyclo[2.2.2]octylene, bicyclo[3.2.1]octylene, bicyclo[3.2.2]nonylene, and bicyclo[3.3.2]decylene, and the like. Cyclic alkylenes also include spirocyclic alkylene in which the linkage to the polymer backbone is through the cyclo or a spiroalkane moiety, as illustrated in structure 19,

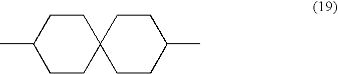

Divalent tricyclo alkylene groups may be exemplified by tricyclo[5.4.0.0.^{2,9}]undecylene, tricyclo[4.2.1.2.^{7,9}]undecylene, tricyclo[5.3.2.0.^{4,}9]dodecylene, and tricyclo[5.2.1.0.^{2,6}]decylene. Diadamantyl is an example of an alkylene. Further examples of alkylene moieties are given in FIG. 1, which may be in the polymer alone or as mixtures or repeat units.

The alkyl group is generally aliphatic and may be cyclic or acyclic (i.e. noncyclic) alkyl having the desirable number of carbon atoms and valence Suitable acyclic groups can be methyl, ethyl, n-or iso-propyl, n-,iso, or tert-butyl, linear or branched pentyl, hexyl, heptyl, octyl, decyl, dodecyl, tetradecyl and hexadecyl. Unless otherwise stated, alkyl refers to a 1-20 carbon atom moiety. The cyclic alkyl groups may be mono cyclic or polycyclic. Suitable example of mono-cyclic alkyl groups include substituted cyclopentyl, cyclohexyl, and cycloheptyl groups. The substituents may be any of the acyclic alkyl groups described herein. Suitable bicyclic alkyl groups include substituted bicyclo[2.2.1]heptane, bicyclo[2.2.2]octane, bicyclo[3.2.1]octane, bicyclo[3.2.2]nonane, and bicyclo[3.3.2]decane, and the like. Examples of tricyclic alkyl groups include tricyclo[5.4.0.0.^{2,9}]undecane, tricyclo[4.2.1.2.^{7,9}]undecane, tricyclo[5.3.2.0.^{4,}9]dodecane, and tricyclo[5.2.1.0.^{2,6}]decane. As mentioned herein the cyclic alkyl groups may have any of the acyclic alkyl groups or aryl groups as substituents.

Aryl groups contain 6 to 24 carbon atoms including phenyl, tolyl, xylyl, naphthyl, anthracyl, biphenyls, bis-phenyls, tris-phenyls and the like. These aryl groups may further be substituted with any of the appropriate substituents e.g. alkyl, alkoxy, acyl or aryl groups mentioned hereinabove. Similarly, appropriate polyvalent aryl groups as desired may be used in this invention. Representative examples of divalent aryl groups include phenylenes, xylylenes, naphthylenes, biphenylenes, and the like.

Alkoxy means straight or branched chain alkoxy having 1 to 20 carbon atoms, and includes, for example, methoxy, ethoxy, n-propoxy, isopropoxy, n-butoxy, isobutoxy, tert-butoxy, pentyloxy, hexyloxy, heptyloxy, octyloxy, nonanyloxy, decanyloxy, 4-methylhexyloxy, 2-propylheptyloxy, and 2-ethyloctyloxy.

Aralkyl means aryl groups with attached substituents. The substituents may be any such as alkyl, alkoxy, acyl, etc. Examples of monovalent aralkyl having 7 to 24 carbon atoms include phenylmethyl, phenylethyl, diphenylmethyl, 1,1- or 1,2-diphenylethyl, 1,1-, 1,2-, 2,2-, or 1,3-diphenylpropyl, and the like. Appropriate combinations of substituted aralkyl groups as described herein having desirable valence may be used as a polyvalent aralkyl group.

Polymer (I) of the present novel composition may be synthesized by reacting a) the aromatic compounds capable of electrophilic substitution such as the aromatic rings that form the backbone of the polymer, with b) at least one essentially aliphatic compound. The comonomeric units are described above and their corresponding monomers are used to form the polymer of the present composition. All the monomers of the monomeric units that comprise polymer (I) may be reacted to form polymer (I). Alternatively polymer (I) is formed by reacting a prepolymer with a reactant compound comprising a fused aromatic group with the corresponding pendant alkanol, that is, Fr₂-alkyleneOH. The prepolymer is formed by reacting the monomers with 3 or more aromatic rings (Fr₁), the monomer with the hydroxyaromatic unit (ArOH) and the monomer with the aliphatic unit (BR₁). The synthesis of the prepolymer is described in U.S. patent application Ser. No. 11/872,962 filed Oct. 16, 2007 and 11/752,040 filed Apr. 9, 2007 and incorporated herein by reference. The aromatic compound for the prepolymer or the polymer may be selected from monomers that provide the desired aromatic unit, more specifically structures 4-9 or 4′-9′ or equivalents, and may be further selected from compounds such as anthracene, phenanthrene, pyrene, fluoranthene, and coronene triphenylene. An additional aromatic monomer with a hydroxy group, such as phenol or naphthol, is also used. The aromatic rings provide at least 2 reactive hydrogens which are sites for electrophilic substitution. The monomer with the aliphatic compound for the prepolymer or the polymer, is an essentially linear, branched or cyclic substituted or unsubstituted alkyl compound capable of forming the aliphatic unit in the polymer, and also capable of forming a carbocation in the presence of an acid, and may be selected from compounds such as aliphatic diol, aliphatic triol, aliphatic tetrol, aliphatic alkene, aliphatic diene, etc. Any compound that is capable of forming the alkylene aliphatic unit in the polymer of the novel composition or prepolymer as described previously may be used. The aliphatic monomer may be exemplified by 1,3-adamantanediol, 1,5-adamantanediol, 1,3,5-adamantanetriol, 1,3,5-cyclohexanetriol, and dicyclopentadiene. Other monomers that provide the hydroxyaromatic unit are added into the reaction mixture, such as phenol and/or naphthol. The reaction is catalyzed in the presence of a strong acid, such as a sulfonic acid. Any sulfonic acid may be used, examples of which are triflic acid, nonafluorobutane sulfonic acid, bisperfluoroalkylimides, trisperfluoroalkylcarbides, or other strong nonnucleophilic acids. The reaction may be carried out with or without a solvent. If a solvent is used then any solvent capable of dissolving the solid components may be used, especially one which is nonreactive towards strong acids; solvents such as chloroform, bis(2-methoxyethyl ether), nitrobenzene, methylene chloride, and diglyme may be used. The reaction may be mixed for a suitable length of time at a suitable temperature, until polymer (I) is formed. The reaction time may range from about 1 hour to about 24 hours, and the reaction temperature may range from about 80° C. to about 180° C. The prepolymer can then be reacted with an aromatic alkanol compound in the presence of an acid catalyst to form the unit of structure (2) of polymer (I). The reaction of the prepolymer can take place in situ or after the isolation of the prepolymer. Examples of the aromatic alkanol compounds are pyrenemethanol, alpha-methyl-9-anthracene methanol, 9-anthracene methanol, and naphthalenemethanol. The aromatic alkanol may be reacted with a phenol or naphthol to form a monomer which is further reacted with the other monomers to form the novel polymer. The polymer may also be formed by reacting the monomers derived from the units described above using the conditions described. The polymer is isolated and purified in appropriate solvents, such as methanol, hexane, cyclohexanone, etc., through precipitation and washing. Known techniques of reacting, isolating and purifying polymer (I) may be used.

The unit of structure (1) in polymer (I) may range from about 5 to about 25 mole % or about 10-15 mole %. The unit of structure (2) in polymer (I) may range from about 5 to about 25 mole % or about 10-15 mole %. The unit of structure (3) in polymer (I) may range from about 10 to about 50 mole % or about 25-30 mole %. The optional hydroxyaromatic unit in the polymer may range from about 0 to about 30 mole % or about 25-30 mole %. The weight average molecular weight of the polymer can range from about 1000 to about 25,000 g/mol, or about 2000 to about 25,000 g/mol or about 2500 to 10,000 g/mol. The refractive indices of polymer (I), n (refractive index) and k (absorption) can range from about 1.3 to about 2.0 for the refractive index and about 0.05 to about 1.0 for the absorption at the exposure wavelength used, such as 193 nm. The carbon content of the composition when using polymer (I) can be in the range of 80 to 95%, preferably 83 to 90%, and more preferably 84 to 89%.

Polymer (II) may be synthesized by reacting a) at least one aromatic compound comprising 3 or more fused aromatic rings capable of electrophilic substitution such that the fused rings form the backbone of the polymer, with b) at least one essentially cycloaliphatic compound to give structure (3a), and at least one aldehyde or equivalent compound to give structure (2a). The comonomeric units are described above and their corresponding monomers are used to form polymer (II) of the present composition. The aromatic compound may be selected from monomers that provide the desired aromatic unit, more specifically structures 4-9 or 4′-9′ or equivalents, and may be further selected from compounds such as anthracene, phenanthrene, pyrene, fluoranthene, and coronene triphenylene. The fused aromatic rings provide at least 2 reactive hydrogens which are sites for electrophilic substitution. The cycloaliphatic compound is a substituted or unsubstituted cyclic compound capable of forming the aliphatic unit in the polymer, and also capable of forming a carbocation in the presence of an acid, and may be selected from compounds such as aliphatic diol, aliphatic triol, aliphatic tetrol, aliphatic alkene, aliphatic diene, etc. Any compound that is capable of forming the alkylene unit in polymer (II) of the novel composition as described previously may be used. The aliphatic monomer may be exemplified by 1,3-adamantanediol, 1,5-adamantanediol, 1,3,5-adamantanetriol, 1,3,5-cyclohexanetriol, and dicyclopentadiene. Any monomer that gives the polymeric unit of structure (2a) may be used, such as paraformaldehyde, formalin, formaldehyde solution in water, acetaldehyde, benzaldehyde, hyroxybenzaldehyde, substituted benzaldehyde, substituted hydroxybenzaldehyde, etc. Other monomers may also be added into the reaction mixture, such as phenol and/or naphthol or substituted phenol and/or substituted naphthol. The reaction is catalyzed in the presence of a strong acid, such as a sulfonic acid. Any sulfonic acid may be used, examples of which are triflic acid, nonafluorobutane sulfonic acid, bisperfluoroalkylimides, trisperfluoroalkylcarbides, or other strong nonnucleophilic acids. The reaction may be carried out with or without a solvent. If a solvent is used then any solvent capable of dissolving the solid components may be used, especially one which is nonreactive towards strong acids; solvents such as chloroform, bis(2-methoxyethyl ether), nitrobenzene, methylene chloride, and diglyme may be used. The reaction may be mixed for a suitable length of time at a suitable temperature, till the polymer is formed. The reaction time may range from about 3 hours to about 24 hours, and the reaction temperature may range from about 80° C. to about 180° C. The polymer is isolated and purified in appropriate solvents, such as methanol, cyclohexanone, etc., through precipitation and washing. Known techniques of reacting, isolating and purifying the polymer may be used.

The unit of structure (1) in polymer (II) may range from about 5 to about 25 mole % or about 10-15 mole %. The unit of structure (2a) in polymer (II) may range from about 5 to about 25 mole % or about 10-15 mole %. The unit of structure (3a) in polymer (II) may range from about 10 to about 50 mole % or about 25-30 mole %. The optional hydroxyaromatic unit in polymer (II) may range from about 0 to about 30 mole % or about 25-30 mole %. The weight average molecular weight of in polymer (II) can range from about 1000 to about 25,000 g/mol, or about 2000 to about 25,000 g/mol or about 2500 to 10,000 g/mol. The refractive indices of polymer (II), n (refractive index) and k (absorption) can range from about 1.3 to about 2.0 for the refractive index and about 0.05 to about 1.0 for the absorption at the exposure wavelength used, such as 193 nm. The carbon content of the composition using polymer (II) can be in the range of 80 to 95%, preferably 83 to 90%, and more preferably 84 to 89%.

The polymer (III) of the present novel composition may be synthesized by reacting a) at least one aromatic compound comprising 3 or more fused aromatic rings capable of electrophilic substitution such that the fused rings form the backbone of the polymer, with b) at least one essentially aliphatic compound. The aromatic compound may be selected from monomers that provide the desired aromatic unit, more specifically structures 4 to 9 or 4′ to 9′ or equivalents, and may be further selected from compounds such as anthracene, phenanthrene, pyrene, fluoranthene, and coronene triphenylene. The fused aromatic rings provide at least 2 reactive hydrogens which are sites for electrophilic substitution. The aliphatic compound is an essentially linear, branched or cyclic substituted or unsubstituted alkyl compound capable of forming the aliphatic unit in the polymer, and also capable of forming a carbocation in the presence of an acid, and may be selected from compounds such as aliphatic diol, aliphatic triol, aliphatic tetrol, aliphatic alkene, aliphatic diene, etc. Any compound that is capable of forming the alkylene unit in polymer (III) of the novel composition as described previously may be used. The aliphatic monomer may be exemplified by 1,3-adamantanediol, 1,5-adamantanediol, 1,3,5-adamantanetriol, 1,3,5-cyclohexanetriol, and dicyclopentadiene. Other monomers may also be added into the reaction mixture, such as phenol and/or naphthol. The reaction is catalyzed in the presence of a strong acid, such as a sulfonic acid. Any sulfonic acid may be used, examples of which are triflic acid, nonafluorobutane sulfonic acid, bisperfluoroalkylimides, trisperfluoroalkylcarbides, or other strong nonnucleophilic acids. The reaction may be carried out with or without a solvent. If a solvent is used then any solvent capable of dissolving the solid components may be used, especially one which is nonreactive towards strong acids; solvents such as chloroform, bis(2-methoxyethyl ether), nitrobenzene, methylene chloride, and diglyme may be used. The reaction may be mixed for a suitable length of time at a suitable temperature, until polymer (III) is formed. The reaction time may range from about 3 hours to about 24 hours, and the reaction temperature may range from about 80° C. to about 180° C. The polymer (III) is isolated and purified in appropriate solvents, such as methanol, cyclohexanone, etc., through precipitation and washing. Known techniques of reacting, isolating and purifying the polymer may be used. The weight average molecular weight of polymer (III) can range from about 1000 to about 50,000, or about 1300 to about 20,000. The refractive indices of polymer (III), n (refractive index) and k (absorption) can range from about 1.3 to about 2.0 for the refractive index and about 0.05 to about 1.0 for the absorption at the exposure wavelength used, such as 193 nm. The carbon content of polymer (III) is greater than 80% as measured by elemental analysis, preferably greater than 85%.

The composition of the present application also comprises a linking component. The linking component can have at least two halogen atoms, at least two alkoxy groups or at least one halogen atom and at least one alkoxy group. Thus, for example, the linking component can be a dichloro compound, a dimethoxy compound or a chloromethoxy compound as well as trichlorodimethoxy, etc, and the like. The linking component can be selected from

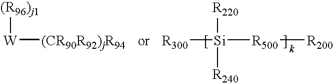

where W is unsubstituted or substituted alkyl, unsubstituted or substituted cycloalkyl, or unsubstituted or substituted aryl; R₉₀ and R₉₂ are each individually hydrogen or unsubstituted or substituted alkyl, unsubstituted or substituted cycloalkyl, or unsubstituted or substituted aryl; R₉₄ is halide or alkoxy; R₉₆ is R₉₀; j is an integer 1 to 6; j1 is an integer 0 to 6; R₅₀₀ is —(—O—)_{w1}— or W; R₂₀₀ is (CR₂₁₀R₂₁₂)ₖ₁R₂₅₀, SiNR₃₁₀R₃₁₂, R_{c}(C═O)(O)ᵥ—, or halogen where R₂₁₀ and R₂₁₂ are each individually hydrogen, unsubstituted or substituted alkyl, unsubstituted or substituted alkenyl, unsubstituted or substituted cycloalkyl, or unsubstituted or substituted aryl; R₂₂₀ and R₂₄₀ are each individually hydrogen or R₂₅₀; R₂₅₀ is OC₁₋₄alkyl, halide, unsubstituted or substituted alkyl, unsubstituted or substituted alkenyl, unsubstituted or substituted cycloalkyl, or unsubstituted or substituted aryl; R₃₁₀ and R₃₁₂ are each individually hydrogen or alkyl; Rc is alkyl, aryl, or cycloalkyl; R₃₀₀ is (CR₂₁₀R₂₁₂)ₖ₁R₂₅₀, SiNR₃₁₀R₃₁₂, R_{c}(C═O)(O)ᵥ—, or halogen; k1 is 0 to 10, k is 1 to 100; w1 is 0 or 1, v is 0 or 1 with the proviso that is w1 is 1, v is 0.

Examples of the linking component include bis-(dibromomethyl) benzene, bis-(dichloropropyl)benzene, bis-(dibromopropyl)benzene, bis-(dichlorobutyl)benzene, bis-(dibromobutyl)benzene, bis-(dichloropentyl)benzene, bis-(dibromopentyl)benzene, bis-(dichlorohexyl)benzene, bis-(dibromohexyl)benzene, bis-(dichloroheptyl)benzene, bis-(dibromoheptyl)benzene, bis-(dichlorooctyl)benzene, bis-(dibromooctyl)benzene, bis-(dichloropropyl)naphthalene, bis-(dichlorobutyl)naphthalene, bis-(dichloropentyl)naphthalene, bis-(dichlorohexyl)naphthalene, bis-(dichloroheptyl)naphthalene, bis-(dichlorooctyl)naphthalene, bis-(dibromopropyl)naphthalene, bis-(dibromobutyl)naphthalene, bis-(dibromopentyl)naphthalene, bis-(dibromohexyl)naphthalene, bis-(dibromoheptyl)naphthalene, bis-(dibromooctyl)naphthalene, bis(methoxymethyl)benzene, bis(2-methoxyethyl)benzene, bis(methoxymethyl)biphenyl, dichlorodimethylsilane, dimethyldimethoxysilane, dimethyldiethoxysilane, dimethyldiisopropoxysilane, dimethyidibutoxysilane, diethyldimethoxysilane, diethyldiethoxysilane, diethyldiisopropoxysilane, diethyldibutoxysilane, diphenyldimethoxysilane, diphenyldiethoxysilane, diphenyldiisopropoxysilane, diphenyldibutoxysilane, dichlorodiethylsilane, dimethyldiacetoxysilane, diethyldiacetoxysilane, diphenyldiacetoxysilane, dichloromethylsilane, dichloromethylvinylsilane, diphenyldichlorosilane, di-t-butylchlorosilane, diphenyldimethoxysilane, ethyl(methoxy)dichlorosilane, ethyl(dimethoxy)chlorosilane, dimethoxydichlorosilane, trimethoxychlorosilane, 1,2-dichlorotetramethyldisilane, 1,2-dichlorotetraethyldisilane, 1,3-dichloro-1,1,3,3-tetraisopropyldisiloxane, 1,1,3,3-tetramethyl-1,3-dichloro-1,3-disiloxane, 1,3-bis(aminopropyl)tetramethyldisiloxane, 1,1,3,3,5,5-hexamethyl-1,5-bis(4-aminophenyl)trisiloxane, 1,1,3,3,5,5-hexamethyl-1,5-bis(3-aminopropyl)trisiloxane, 1,1,3,3,5,5-hexapropyl-1,5-bis(3-aminopropyl)trisiloxane, 1,3-diethoxytrisilane, 1,7-dichloro-1,1,3,3,5,5,7,7-octamethyltetrasiloxane, 1,7-dimethoxy-1,1,3,3,5,5,7,7-octamethyltetrasiloxane, poly(dimethoxysilane), and the like. Mixtures of the linking component can be used.

The novel composition of the present invention also comprises a crosslinker. Typically the crosslinker is a compound that can act as an electrophile and can, alone or in the presence of an acid, form a carbocation. Thus compounds containing groups such as alcohol, ether, ester, olefin, methoxymethylamino, methoxymethylphenyl and other molecules containing multiple electrophilic sites, are capable of crosslinking with the polymer. Examples of compounds which can be crosslinkers are, 1,3-adamantanediol, 1,3,5-adamantanetriol, polyfunctional reactive benzylic compounds, tetramethoxymethyl-bisphenol (TMOM-BP) of structure (20), aminoplast crosslinkers, glycolurils, Cymels, Powderlinks, etc.

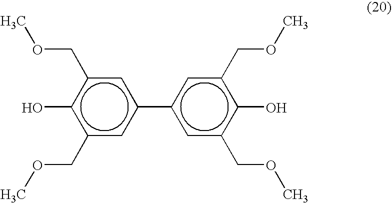

The novel composition also comprises an acid generator. The acid generator can be a thermal acid generator capable of generating a strong acid upon heating. The thermal acid generator (TAG) used in the present invention may be any one or more that upon heating generates an acid which can react with the polymer and propagate crosslinking of the polymer present in the invention, particularly preferred is a strong acid such as a sulfonic acid. Preferably, the thermal acid generator is activated at above 90° C. and more preferably at above 120° C., and even more preferably at above 150° C. Examples of thermal acid generators are metal-free sulfonium salts and iodonium salts, such as triarylsulfonium, dialkylarylsulfonium, and diarylakylsulfonium salts of strong non-nucleophilic acids, alkylaryliodonium, diaryliodonium salts of strong non-nucleophilic acids; and ammonium, alkylammonium, dialkylammonium, trialkylammonium, tetraalkylammonium salts of strong non nucleophilic acids. Also, covalent thermal acid generators are also envisaged as useful additives for instance 2-nitrobenzyl esters of alkyl or arylsulfonic acids and other esters of sulfonic acid which thermally decompose to give free sulfonic acids. Examples are diaryliodonium perfluoroalkylsulfonates, diaryliodonium tris(fluoroalkylsulfonyl)methide, diaryliodonium bis(fluoroalkylsulfonyl)methide, diarlyliodonium bis(fluoroalkylsulfonyl)imide, diaryliodonium quaternary ammonium perfluoroalkylsulfonate. Examples of labile esters: 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; quaternary ammonium tris(fluoroalkylsulfonyl)methide, and quaternaryalkyl ammonium bis(fluoroalkylsulfonyl)imide, alkyl ammonium salts of organic acids, such as triethylammonium salt of 10-camphorsulfonic acid. A variety of aromatic (anthracene, naphthalene or benzene derivatives) sulfonic acid amine salts can be employed as the TAG, including those disclosed in U.S. Pat. Nos. 3,474,054, 4,200,729, 4,251,665 and 5,187,019. Preferably the TAG will have a very low volatility at temperatures between 170-220° C. Examples of TAGs are those sold by King Industries under Nacure and CDX names. Such TAGs include Nacure 5225, and CDX-2168E, which is a dodecylbenzene sulfonic acid amine salt supplied at 25-30% activity in propylene glycol methyl ether from King Industries, Norwalk, Conn. 06852, USA.

The novel composition may further contain at least one of the known photoacid generators, examples of which without limitation are onium salts, sulfonate compounds, nitrobenzyl esters, triazines, etc. The preferred photoacid generators are onium salts and sulfonate esters of hydoxyimides, specifically diphenyl iodonium salts, triphenyl sulfonium salts, dialkyl iodonium salts, triakylsulfonium salts, and mixtures thereof. These photoacid generators are not necessarily photolysed but are thermally decomposed to form an acid.

The antireflection coating composition of the present invention may contain 1 weight % to about 15 weight % of the polymers described herein, and preferably 4 weight % to about 10 weight %, of total solids. The linking component is present at about 1 weight % to about 30 weight % of total solids. The crosslinker is present at about 1 weight % to about 30 weight % of total solids. The acid generator, may be incorporated in a range from about 0.1 to about 10 weight % by total solids of the antireflective coating composition, preferably from 0.3 to 5 weight % by solids, and more preferably 0.5 to 2.5 weight % by solids.

The solid components of the antireflection coating composition are mixed with a solvent or mixtures of solvents that dissolve the solid components of the antireflective coating. Suitable solvents for the antireflective coating composition may include, for example, a glycol ether derivative such as ethyl cellosolve, methyl cellosolve, propylene glycol monomethyl ether (PGME), diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate (PGMEA); carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate (EL), ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof.

Other components may be added to the antireflective coating composition enhance the performance of the coating, e.g. monomeric dyes, lower alcohols (C₁-C₆ alcohols), surface leveling agents, adhesion promoters, antifoaming agents, etc.

Since the antireflective film is coated on top of the substrate and is also subjected to dry etching, it is envisioned that the film is of sufficiently low metal ion level and of sufficient purity that the properties of the semiconductor device are not adversely affected. Treatments such as passing a solution of the polymer through an ion exchange column, filtration, and extraction processes can be used to reduce the concentration of metal ions and to reduce particles.

The absorption parameter (k) of the novel composition ranges from about 0.05 to about 1.0, preferably from about 0.1 to about 0.8 at the exposure wavelength, as derived from ellipsometric measurements. In one embodiment the composition has a k value in the range of about 0.2 to about 0.5 at the exposure wavelength. The refractive index (n) of the antireflective coating is also optimized and can range from about 1.3 to about 2.0, preferably 1.5 to about 1.8. The n and k values can be calculated using an ellipsometer, such as the J. A. Woollam WVASE VU-32™ Ellipsometer. The exact values of the optimum ranges for k and n are dependent on the exposure wavelength used and the type of application. Typically for 193 nm the preferred range for k is about 0.05 to about 0.75, and for 248 nm the preferred range for k is about 0.1 5 to about 0.8.

The carbon content of the novel antireflective coating composition is greater than 80 weight %, and more preferably 84 to 89% as measured by elemental analysis.

The antireflective coating composition is coated on the substrate using techniques well known to those skilled in the art, such as dipping, spin coating or spraying. Typically, the film thickness of the antireflective coating ranges from about 15 nm to about 1,000 nm. Different applications require different film thicknesses. The coating is further heated on a hot plate or convection oven for a sufficient length of time to remove any residual solvent and induce crosslinking, and thus insolubilizing the antireflective coating to prevent intermixing between the antireflective coating and the layer to be coated above it. The preferred range of temperature is from about 90° C. to about 280° C.

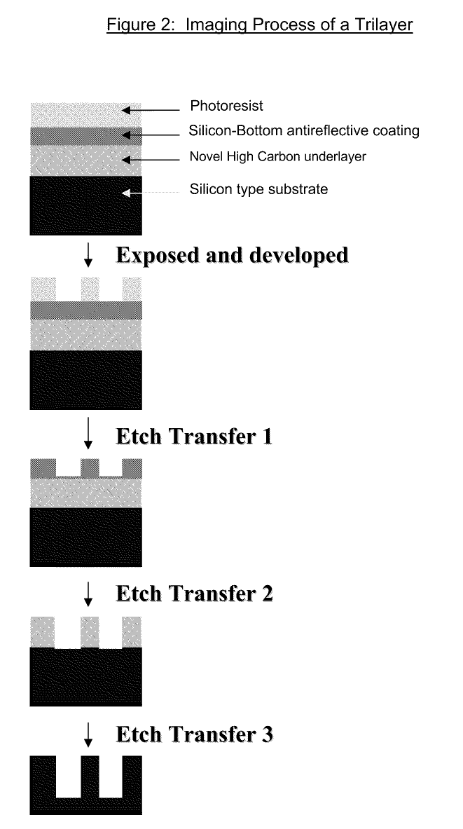

Other types of antireflective coatings may be coated above the coating of the present invention. Typically, an antireflective coating which has a high resistance to oxygen etching, such as one comprising silicon groups, such as siloxane, functionalized siloxanes, silsesquioxanes, or other moieties that reduce the rate of etching, etc., is used so that the coating can act as a hard mask for pattern transference. The silicon coating can be spin coatable or chemical vapor deposited. In one embodiment the substrate is coated with a first film of the novel composition of the present invention and a second coating of another antireflective coating comprising silicon is coated above the first film. The second coating can have an absorption parameter (k) value in the range of about 0.05 and 0.5. A film of photoresist is then coated over the second coating. The imaging process is exemplified in FIG. 2.

A film of photoresist is coated on top of the uppermost antireflective coating and baked to substantially remove the photoresist solvent. An edge bead remover may be applied after the coating steps to clean the edges of the substrate using processes well known in the art.

The substrates over which the antireflective coatings are formed can be any of those typically used in the semiconductor industry. Suitable substrates include, without limitation, low dielectric constant materials, silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/V compounds. The substrate may comprise any number of layers made from the materials described above.

Photoresists can be any of the types used in the semiconductor industry, provided the photoactive compound in the photoresist and the antireflective coating substantially absorb at the exposure wavelength used for the imaging process.

To date, there are several major deep ultraviolet (uv) exposure technologies that have provided significant advancement in miniaturization, and these radiation of 248 nm, 193 nm, 157 and 13.5 nm. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure at 193 nm and 157 nm require non-aromatic polymers since aromatics are opaque at this wavelength. U.S. Pat. No. 5,843,624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures. U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference. Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587, and U.S. Pat. No. 6,849,377) using either metal catalyzed or radical polymerization. Generally, these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (U.S. Pat. No. 6,818,258) or copolymerization of a fluorodiene with an olefin (U.S. Pat. No. 6,916,590). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art. The novel coatings can also be used in nanoimprinting and e-beam lithography.

After the coating process, the photoresist is imagewise exposed. The exposure may be done using typical exposure equipment. The exposed photoresist is then developed in an aqueous developer to remove the treated photoresist. The developer is preferably an aqueous alkaline solution comprising, for example, tetramethyl ammonium hydroxide (TMAH). The developer may further comprise surfactant(s). An optional heating step can be incorporated into the process prior to development and after exposure.

The process of coating and imaging photoresists is well known to those skilled in the art and is optimized for the specific type of photoresist used. The patterned substrate can then be dry etched with an etching gas or mixture of gases, in a suitable etch chamber to remove the exposed portions of the antireflective film or multiple layers of antireflective coatings, with the remaining photoresist acting as an etch mask. Various etching gases are known in the art for etching organic antireflective coatings, such as those comprising O₂, CF₄, CHF₃, Cl₂, HBr, SO₂, CO, etc.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

The refractive index (n) and the absorption parameter (k) values of the antireflective coating in the Examples below were measured on a J. A. Woollam VASE32 ellipsometer.

The molecular weight of the polymers was measured on a Gel Permeation Chromatograph.

### Example 1

### Synthesis of Poly(Anthracene-co-1-Naphthol-co-Phenol-co-Adamantane diol).

Anthracene (8.9 g, 0.05 mole) and 1,3-adamantane diol (16.8 g, 0.1 mole), 1-naphthol (7.2 g, 0.1 mole) and phenol (9.4 g, 0.1 mole) were taken into a 500 mL 4 neck round bottomed flask (RBF) equipped with stirrer, condenser, Dean Stark trap, Thermo watch and N₂ source. 140 g of diglyme and 40 g of cyclopentylmethylether (CPME) were added, mixed for 10 minutes under nitrogen and 1.50 g of trifluoromethane sulfonic acid was added. The flask was heated to reflux at 140° C., for three hours. After the reaction, the flask was cooled to room temperature. The reaction mixture was mixed with 1.4 liters of methanol and a precipitate was formed. The precipitate was filtered through a Buckner Funnel and dried under vacuum. The crude polymer was redissolved in CPME, washed with water three times and then drowned in 1.5 liters of hexane. A precipitate was formed, filtered, washed with hexane and dried under vacuum. 20.0 g of the polymer was obtained with a yield of 50%, and the weight average molecular weight, Mw, was 2946, with a polydispersity of 1.57.

### Example 2

### Synthesis of Poly(alpha methyl-9-Anthracene methanol-co-Anthracenemethyl-co-Anthracene-co-1-Naphthol-co-Phenol-co-Adamantane).

Anthracene 8.9 g (0.05 mole), 1-naphthol 7.2 g (0.05 mole), 1,3-adamantane diol 16.8 g (0.10 mole), phenol 16.8 g (0.1 mole), alpha methyl-9-anthracene methanol (22.2 g., 0.1 mole), 210 g diglyme, and 210 g of CPME, were weighed together in a 1000 mL, 4 neck, RBF equipped with overhead mechanical stirring, condenser, thermo watch, Dean Stark trap, and N₂ source. The components were mixed together at room temp for 10 minutes and 2.5 g of triflic acid was added. The mixture was stirred at room temperature for 5 minutes and then the temperature was set to 140° C. As the temperature increased, the water was removed from the reaction using the Dean Stark trap. The reaction was allowed to proceed for 3 hours at 140° C. The reaction mixture was precipitated by drowning into 3 L hexane. The polymer was very sticky and was isolated by decanting the liquid. The polymer was dissolved in 700 mL CPME and 150 mL of THF and was washed with 500 mL Di water. This was repeated five times and then when added to 3 liters of hexane, a precipitate was formed, filtered, washed, and dried under vacuum at 55° C. overnight. The dry polymer was dissolved in 400 mL THF and precipitated by drowning into 3 L hexane. The precipitate was filtered, washed, and dried overnight under vacuum at 55° C.. The polymer had a GPC weight average Mw of 4922, and polydispersity of 2.13.

### Example 3

Tetramethoxysilane, 60.8 g (0.4 mole), and Amberlyst™ 15 ionic exchange resin, 1.2 g, were mixed together in a 250 mL flask. Then, deionized water, 7.92 g (0.44 mole), was added dropwise into the mixture slowly under stirring. After addition of the deionized water was complete, the mixture was then stirred at room temperature for 4 hours. Amberlyst 15 ionic exchange resin was filtered off. The clear solution was subjected to vacuum to remove methanol formed during the sol-gel condensation. The final product was a clear and viscous liquid having a GPC weight average Mw of 9876, and polydispersity of 1.75.

### Example 4

1.5 g of the polymer from Example 1 was taken in a bottle and 0.15 g of TMOM-BP, 4% of poly(dimethoxysiloxane) from Example 3 (or poly(dimethoxysiloxane) from Gelest (e.g., PSI-026)), 0.6 g of DBSA at 10% solution in ArF Thinner (available from AZ Electronic Materials), and 12.75 g of ArF Thinner was added to make 15.00 g of solution. After shaking over night, the solution was filtered using 0.2 μm filter.

### Example 5

N & K Measurement: The solution from Example 4 was adjusted to 1.25% solids with ArF Thinner and the mixture was allowed to mix until homogeneous. The homogeneous solution was filtered using a 0.2 μm membrane filter. The filtered solution was spin-coated on a 6″ silicon wafer at 1500 rpm. The coated wafer was then baked on a hotplate at 230° C. for 60 seconds. n and k values were measured with a VASE Ellipsometer manufactured by J. A. Woollam Co. Inc. The optical constants, n and k, for the underlayer film at 193 nm radiation were n=1.47 and k=0.48

### Example 6

The solution from Example 4 was spin-coated on a 6″ silicon wafer at 1500 rpm. The coated wafer was then baked on a hotplate at 230° C. for 60 seconds. After baking, the wafer was cooled to room temperature and partially submerged in PGME for 30 seconds. The two halves of the wafer (submerged and non-submerged) were examined for changes in film thickness. No film loss was observed.

### Example 7

Lithography exposures were performed on a Nikon NSR-306D (NA: 0.85) interfaced to a Tokyo Electron Clean Track 12. A trilayer stack was prepared as follows: the solution from Example 4 was spin-coated on an 8″ silicon wafer at 1500 rpm to a film thickness of 200 nm and then baked at 230° C. for 60 sec; then Si-BARC S24H (available from AZ Electronic Materials USA Corp.) was coated over and baked at 230° C. for 60 sec to a film thickness of 38 nm; and then a resist (AX2110P; available from AZ Electronic Materials USA Corp.) was coated over at a film thickness of 150 nm. Exposure patterns for 100 nm 1:1 line and space were processed at PAB (post-applied bake) of 110° C./60 s and PEB (post-exposure bake) of 110° C./60 s; dipole illumination (0.82 outer, 0.43 inner sigma) and the exposed/baked wafers were developed for 30 seconds with a surfactant-free developer (AZ® 300MIF, containing 2.38% tetramethyl ammonium hydroxide (TMAH)). Line/space (1:1), 80 nm resolution was resolved.

### Example 8

Lithography exposures were performed on a Nikon NSR-306D (NA: 0.85) interfaced to a Tokyo Electron Clean Track 12. A trilayer stack was prepared as follows: the solution from Example 4 was spin-coated on an 8″ silicon wafer at 1500 rpm to a film thickness of 260 nm and then baked at 230° C. for 60 sec; then Si-BARC S24H (available from AZ Electronic Materials USA Corp.) was coated over and baked at 230° C. for 60 sec to a film thickness of 38 nm; and then a resist (AX2050P; available from AZ Electronic Materials USA Corp.) was coated over at a film thickness of 200 nm. Exposure patterns for 100 nm 1:1 contact hole were processed at PAB (post-applied bake) of 110° C./60 s and PEB (post-exposure bake) of 110° C./60 s; dipole illumination (0.82 outer, 0.43 inner sigma) and the exposed/baked wafers were developed for 60 seconds with a surfactant-free developer (AZ® 300MIF, containing 2.38% tetramethyl ammonium hydroxide (TMAH)). The CD measured was 109 nm.

### Example 9

The patterned wafer from Example 8 was etched in NE-5000N (ULVAC) Etcher initially with Si-BARC etching condition with CF₄ 50 SCCM, under pressure 10PA, top power 500, wafer power 250 for 20 seconds, followed by oxygen etching with O₂ 4 SCCM and N₂ SCCM, and Ar 25SCCM under pressure 0.26 Pa, top power 200, wafer power 100, for 45, 60, and 75 seconds. The pattern shape after etching was vertical.

### Example 10

1.5 g of the polymer from Example 2 was taken in a bottle and 0.15 g of TMOM-BP, 4% of poly(dimethoxysiloxane) from Example 3 (or poly(dimethoxysiloxane) from Gelest, PSI-026), 0.6 g of DBSA at 10% solution in ArF Thinner, and 12.75 g of ArF Thinner was added to make 15.00 g of solution. After shaking over night, the solution was filtered using 0.2 μm filter.

### Example 11

N & K Measurement: The solution from Example 10 was adjusted to 1.25% solid with ArF Thinner and the mixture was allowed to mix until homogeneous. The homogeneous solution was filtered using a 0.2 μm membrane filter. The filtered solution was spin-coated on a 6″ silicon wafer at 1500 rpm. The coated wafer was then baked on a hotplate at 230° C. for 60 seconds. n and k values were measured with a VASE Ellipsometer manufactured by J. A. Woollam Co. Inc. The optical constants, n and k, for the underlayer film at 193 nm radiation were n=1.45, k=0.41.

### Example 12

The solution from Example 10 was spin-coated on a 6″ silicon wafer at 1500 rpm. The coated wafer was baked on a hotplate at 230° C. for 60 seconds. After baking, the wafer was cooled to room temperature and partially submerged in PGME for 30 seconds. The two halves of the wafer (submerged and non-submerged) were examined for changes in film thickness. No film loss was observed.

### Example 13

Lithography exposures were performed on a Nikon NSR-306D (NA: 0.85) interfaced to a Tokyo Electron Clean Track 12. A trilayer stack was prepared as follows: the solution from Example 10 was spin-coated on an 8″ silicon wafer at 1500 rpm to a film thickness of 200 nm and then baked at 230° C. for 60 sec; then Si-BARC S24H (available from AZ Electronic Materials USA Corp.) was coated over and baked at 230° C. for 60 sec to a film thickness of 38 nm; and then a resist (AX2110P; available from AZ Electronic Materials USA Corp.) was coated over at a film thickness of 150 nm. Exposure patterns for 100 nm 1:1 line and space were processed at PAB (post-applied bake) of 110° C./60 s and PEB (post-exposure bake) of 110° C./60 s; dipole illumination (0.82 outer, 0.43 inner sigma) and the exposed/baked wafers were developed for 30 seconds with a surfactant-free developer (AZ® 300MIF, containing 2.38% tetramethyl ammonium hydroxide (TMAH)). Line/space (1:1), 80 nm resolution was resolved.

### Example 14

Lithography exposures were performed on a Nikon NSR-306D (NA: 0.85) interfaced to a Tokyo Electron Clean Track 12. A trilayer stack was prepared as follows: the solution from Example 10 was spin-coated on an 8″ silicon wafer at 1500 rpm to a film thickness of 260 nm and then baked at 230° C. for 60 sec; then Si-BARC S24H (available from AZ Electronic Materials USA Corp.) was coated over and baked at 230° C. for 60 sec to a film thickness of 38 nm; and then a resist (AX2050P; available from AZ Electronic Materials USA Corp.) was coated over at a film thickness of 200 nm. Exposure patterns for 100 nm 1:1 contact hole were processed at PAB (post-applied bake) of 110° C./60 s and PEB (post-exposure bake) of 110° C./60 s; dipole illumination (0.82 outer, 0.43 inner sigma) and the exposed/baked wafers were developed for 60 seconds with a surfactant-free developer (AZ® 300MIF, containing 2.38% tetramethyl ammonium hydroxide (TMAH)). The CD measured was 109 nm.

### Example 15

The pattern wafer from Example 14 was etched in NE-5000N (ULVAC) Etcher initially with Si-BARC etching condition with CF₄ 50 SCCM, under pressure 10 PA, top power 500, wafer power 250 for 20 seconds, followed by oxygen etching with O₂ 4 SCCM and N₂ SCCM, and Ar 25SCCM under pressure 0.26 Pa, top power 200, wafer power 100, for 45, 60, and 75 seconds. The pattern shape after etching was vertical.

1. An organic spin coatable antireflective coating composition comprising
(a) a polymer selected from
(I) a polymer with (i) at least one unit with three or more fused aromatic rings of structure (1) in the backbone of the polymer, (ii) at least one aromatic ring unit of structure (2) where the aromatic ring has a pendant alkylene(fused aromatic) group and a pendant hydroxy group in the backbone of the polymer, and, (iii) at least one unit with an aliphatic moiety B of structure (3) in the backbone of the polymer 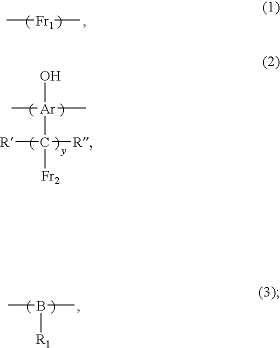
(II) a polymer where the polymer comprises (i) at least one unit with fused aromatic rings of structure (1) in the backbone of the polymer, (ii) at least one unit with structure (2a) in the backbone of the polymer, and, (iii) at least one unit with a cyclic aliphatic moiety D of structure (3a) in the backbone of the polymer 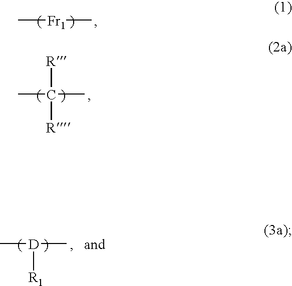
(III) a polymer comprising at least one unit with 3 or more fused aromatic rings Fr₁ in the backbone of the polymer and at least one unit with an aliphatic moiety in the backbone of the polymer,
where Fr₁ is a substituted or unsubstituted fused aromatic ring moiety with 3 or more fused aromatic rings, Fr₂ is a fused aromatic ring moiety with 2 or more fused aromatic rings, Ar is a substituted or unsubstituted aromatic ring moiety, R′ and R″ are independently selected from hydrogen and C₁-C₄ alkyl, R′″ and R″″ are independently selected from hydrogen, C₁-C₄ alkyl, Z, C₁-C₄alkyleneZ where Z is substituted or unsubstituted aromatic moiety, y=1-4, B is a substituted or unsubstituted aliphatic moiety, D is a substituted or unsubstituted cycloaliphatic moiety, and R₁ is selected from hydrogen or aromatic moiety;
(b) a linking component having at least two halogen atoms, at least two alkoxy groups or at least one halogen atom and at least one alkoxy group;
(c) a crosslinker; and
(d) an acid generator.

2. The composition of claim 1, where the unit with the fused aromatic rings has about 3 to about 8 aromatic rings.

3. The composition of claim 1, where the unit with the fused aromatic rings has 4 or more aromatic rings.

4. The composition of claim 1, where Fr₁ is selected from, 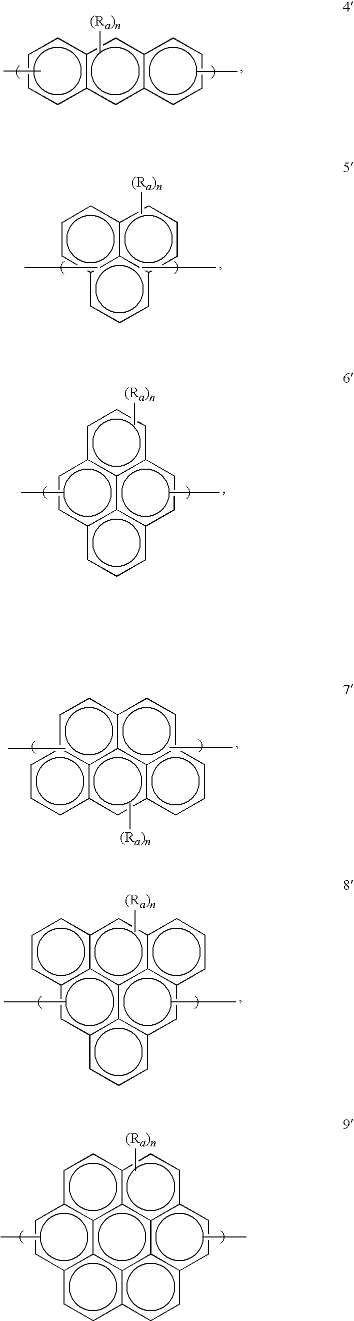
where Rₐ is an organo substituent, and n is 1-12.

5. The composition of claim 1, where for polymer of (I), the aliphatic moiety B is selected from at least one of an unsubstituted or substituted linear alkylene group, an unsubstituted or substituted branched alkylene group, an unsubstituted or substituted cycloalkylene group, or a mixture thereof.

6. The composition of claim 1, where the polymer of (I) further comprises at least one aromatic unit in the backbone of the polymer where the aromatic unit has a pendant hydroxy group.

7. The composition of claim 1, where for polymer of (I) the unit (iii) forms a block unit comprising more than 1 cycloaliphatic unit.

8. The composition of claim 1, where for polymer of (I) the polymer further comprises a monomeric unit comprising a group selected from at least one of unsubstituted phenol, substituted phenol, unsubstituted naphthol, substituted naphthol, unsubstituted biphenyl and substituted biphenyl.

9. The composition of claim 1, where for polymer of (I) the unit with the aliphatic moiety B has sites which can react with a crosslinker.

10. The composition of claim 1, where for polymer of (II) the unit (ii) is selected from methylene, alkylmethylene, aryl substituted methylene, hydroxyaryl substituted methylene, and hydroxyaryl substituted alkylmethylene.

11. The composition of claim 1 where for polymer of (II) the cyclic aliphatic moiety D is an cycloalkylene substituted with at least one group selected from a hydroxy, hydroxyalkyl, carboxylic acid, carboxylic ester, alkylether, alkoxy alkyl, ethers, haloalkyls, alkylcarbonates, alkylaldehydes, and ketones.

12. The composition of claim 1, where for polymer of (II) the cycloaliphatic group forms a block unit comprising more than 1 cycloaliphatic unit.

13. The composition of claim 1, where for polymer of (II) the polymer further comprises a monomeric unit comprising a group selected from at least one of unsubstituted phenyl, substituted phenyl, unsubstituted naphthyl and substituted naphthyl.

14. The composition of claim 1, where for polymer of (II) the polymer further comprises a unit selected from at least one of hydroxyphenyl, hydroxynaphthyl, and hydroxybiphenyl.

15. The composition of claim 1, where for polymer of (II) the unit with the aliphatic moiety has sites which can react with a crosslinker.

16. The composition of claim 1, where for polymer of (III) the aliphatic moiety is selected from an unsubstituted or substituted linear alkylene group, an unsubstituted or substituted branched alkylene group, an unsubstituted or substituted cycloalkylene group, or a mixture thereof.

17. The composition of claim 1, where for polymer of (III) the aliphatic moiety is a mixture of unsubstituted alkylene and a substituted alkylene.

18. The composition of claim 23, where for polymer of (III) the cycloalkene group forms a block unit comprising more than 1 cycloaliphatic unit.

19. The composition of claim 1, where for polymer of (III) the polymer further comprises a monomeric unit comprising a group selected from at least one of unsubstituted phenyl, substituted phenyl, unsubstituted naphthyl and substituted naphthyl.

20. The composition of claim 1, where for polymer of (III) the polymer further comprises a monomeric unit comprising a group selected from at least one of unsubstituted phenol, substituted phenol, unsubstituted naphthol, substituted naphthol, unsubstituted biphenyl and substituted biphenyl.

21. The composition of claim 1, where (b) the linking component has the formula selected from 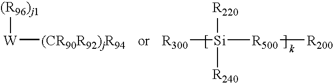
where W is unsubstituted or substituted alkyl, unsubstituted or substituted cycloalkyl, or unsubstituted or substituted aryl; R₉₀ and R₉₂ are each individually hydrogen or unsubstituted or substituted alkyl, unsubstituted or substituted cycloalkyl, or unsubstituted or substituted aryl; R₉₄ is halide or alkoxy; R₉₆ is R₉₀; j is an integer 1 to 6; j1 is an integer 0 to 6; R₅₀₀ is —(—O—)_{w1}— or W; R₂₀₀ is (CR₂₁₀R₂₁₂)ₖ₁R₂₅₀, SiNR₃₁₀R₃₁₂, R_{c}(C═O)(O)ᵥ—, or halogen where R₂₁₀ and R₂₁₂ are each individually hydrogen, unsubstituted or substituted alkyl, unsubstituted or substituted alkenyl, unsubstituted or substituted cycloalkyl, or unsubstituted or substituted aryl; R₂₂₀ and R₂₄₀ are each individually hydrogen or R₂₅₀; R₂₅₀ is OC₁₋₄alkyl, halide, unsubstituted or substituted alkyl, unsubstituted or substituted alkenyl, unsubstituted or substituted cycloalkyl, or unsubstituted or substituted aryl; R₃₁₀ and R₃₁₂ are each individually hydrogen or alkyl; Rc is alkyl, aryl, or cycloalkyl; R₃₀₀ is (CR₂₁₀R₂₁₂)ₖ₁R₂₅₀, SiNR₃₁₀R₃₁₂, R_{c}(C═O)(O)ᵥ—, or halogen; k1 is 0 to 10, k is 1 to 100; w1 is 0 or 1, v is 0 or 1 with the proviso that is w1 is 1, is 0.

22. The composition of claim 1, where the composition is not photoimageable.

23. A process for manufacturing a microelectronic device, comprising;
a) providing a substrate with a first layer of an antireflective coating composition from claim 1;
b) optionally, providing at least a second antireflective coating layer over the first antireflective coating composition layer;
c) coating a photoresist layer above the antireflective coating layers;
d) imagewise exposing the photoresist layer;
e) developing the photoresist layer with an aqueous alkaline developing solution.

24. The process of claim 23, where the second antireflective coating comprises silicon.

25. The process of claim 23, where the photoresist is imageable with radiation from about 240 nm to about 12 nm or nanoimprinting.

26. The process of claim 23, further dry etching the layer(s) beneath the photoresist.
